(19) United States
(12) Patent Application Publication
(10) Pub. No.: US 2013/0118542 A1
(43) Pub. Date: May 16, 2013

(54) Energy Generation Device

(71) Applicant: George S. Levy, San Diego, CA (US)

(72) Inventor: George Samuel Levy, San Diego, CA (US)

(73) Assignee: George S. Levy, San Diego, CA (US)

(21) Appl. No.: 13/668,914

(22) Filed: Nov. 5, 2012

Related U.S. Application Data
(63) Continuation of application No. 61/610,315, filed on Mar. 13, 2012.
(60) Provisional application No. 61/558,603, filed on Nov. 11, 2011.
(60) Provisional application No. 61/567,455, filed on Dec. 6, 2011.
(60) Provisional application No. 61/583,185, filed on Jan. 5, 2012.
(60) Provisional application No. 61/594,354, filed on Feb. 2, 2012.

(51) Int. Cl. H01L 35/32; F03G 7/04

(52) U.S. Cl. CPC H01L 35/32; F03G 7/04
USPC 136/205; 60/641.1

(57) ABSTRACT

An energy generator capable of transferring heat from a cold region to a hot region, which utilizes the adiabatic temperature difference called lapse rate generated in gas or gas-like particles when a force field or an energy potential gradient is applied to the particles. The temperature difference is increased by the thermal conductivity of the particles and lowered by the thermal conductivity of the substrate or container holding the particles and by parasitic thermal shorts caused by photons, phonons, or other particles not subjected or less affected by the force field. Implementations include semiconductors with a doping gradient or with an externally applied voltage; vapors in contact with their liquids; gases in contact with adsorbing surfaces; polar molecules with electrons in the conduction band. Multilayer devices are described. Applications include, for example, coolers, heaters, electrical generators and photon generators.

### FIELD OF THE INVENTION

The present invention relates to engines that generate energy from adiabatic temperature differences generated by particles in a gas or vapor phase, or charge carriers behaving like a gas in a semiconductor, when these particles are subjected to a potential energy gradient such as gravity, the electric field, van der Waals and liquid/vapor interfaces.

This invention claims the priority benefit of:

U.S. provisional application No. 61/558,603 titled “Energy Generation Engine” filed on Nov. 11, 2011;
U.S. provisional application No. 61/567,455 titled “Energy Generation Engine” filed on Dec. 6, 2011;
U.S. provisional application No. 61/583,185 titled “Energy Generation Engine” filed on Jan. 5, 2012;
U.S. provisional application No. 61/594,354 titled “Energy Generation Engine” filed on Feb. 2, 2012;
U.S. provisional application No. 61/610,315 titled “Energy Generation Engine” filed on Mar. 13, 2012;
all of which are hereby incorporated by reference. Applicant claims priority pursuant to 35U.S.C. Par 119(e)(i).

It is understood that the sequence of aforesaid provisional patent applications represents the results of continuing research which has yielded over time a better and improved understanding of nature and a more accurate formulation of natural laws. It is also understood that the patentability of this invention should be governed, not by any (scientific) “belief” system which could become obsolete as science progresses, but by the utility of the invention. Therefore, if any disclosures in the parent utility application and parent provisional applications, or in the patents incorporated herein by reference conflict in part or whole with the present disclosure, then to the extent of conflict, and/or broader disclosure, and/or broader definition of terms, the present disclosure controls. If such incorporated disclosures conflict in part or whole with one another, then to the extent of conflict, the later-dated disclosure controls. If prior art conflicts with prior art, then the present disclosure controls.

### PATENTS INCORPORATED BY REFERENCE

The aforesaid patent applications have been incorporated by reference. The following patents and applications are also incorporated by reference. U.S. Pat. No. 5,550,387 by Elsner et al “Superlattice Quantum Well Material”

U.S. Pat. No. 5,856,210 by Leavitt et al, “Method of fabricating a thermoelectric module with gapless eggcrate.
U.S. Pat. No. 5,875,098 by Leavitt et al., “Thermoelectric Module with Gapless Eggcrate”
U.S. Pat. No. 6,096,964 by Ghamaty et al, “Quantum Well Thermoelectric Material on Thin Flexible Substrate.”
U.S. Pat. No. 6,096,965 by Ghamaty et al. “Quantum Well Thermoelectric Material on Organic Substrate.”
U.S. Pat. No. 6,828,579 by Ghamaty et al. “Thermoelectric Device with SI/SIC Superlattice N-Legs”.
U.S. Pat. No. 7,038,234 by Ghamaty et al. “Thermoelectric Module with SI/SIGE and B4C/B9C Super-Lattice Legs”.
U.S. Pat. No. 7,342,170 by Ghamaty et al. “Thermoelectric Module with SI/SIC and B4C/B9C Super-Lattice Legs”.
U.S. Pat. No. 7,400,050 by Jovanovic et al, “Quantum Well Thermoelectric Poser Source.”
US Patent Application 2008/0257395 by Jovanovic et al, “Miniature Quantum Well Thermoelectric device.”

### US Patent Application 2010/0229911 by Leavitt et al, “High Temperature, High Efficiency Thermoelectric Module.”

### US Patent Application 2011/0062420 by Ghamaty et al., Quantum Well Thermoelectric Module.”

US Patent Application 2008/0257395 by Jovanovic et al, “Miniature Quantum Well Thermoelectric device.”
US Patent Application 2011/0100408 by Kushch et al., “Quantum Well Module with Low K Crystalline Covered Substrates.”

### OTHER REFERENCES

Prior art reference are listed below.
1) TOKAI-MURA, IBARAKI-KEN, “Adsorption equilibrium of hydrogen isotopes on alumina adsorbents for gas-solid chromatography, by Toshihiko Yamanishi, Hiroshi Kudo, Japan Atomic Energy Research Institute, 319-11 Japan, Received 1 Sep. 1988; revised 4 Apr. 1989; Available online 3 Jan. 2002
2) VAN ZEGHBROECK, B. “Principles of Electronic Devices”, 2011.
3) CAMPBELL, TIMOTHY; KALIA, RAJIV; NAKANO AIICHIRO; VASHISHTA PRIYA; OGATA, SHUJI; RODGERS, STEPHE, “Dynamics of Oxidation of Aluminum Nanoclusters using Variable Charge Molecular-Dynamics Simulations on Parallel Computers”.Physical Review Letters 82 (24): 4866. (1999). Bibcode 1999PhRvL.82.4866C.doi:10.1103/PhysRevLett.82.4866).
4) ANDREA TRUPP, “Energy, Entropy: On the Occasion of the 100th Anniversary of Josef Loschmidt's Death in 1895: Is Loschmidt's Greatest Discovery Still Waiting for Its Discoverer?”, Physics Essays Vlume 12, Number 4, 1999. Pages 614-628.
5) ANDREA TRUPP, “Second Law Violations by Means of a Stratification of Temperature Due to Force Fields,” CP643, Quantum Limits to the Second Law: First International Conference, Edited by D. P. Sheehan, 2002 American Institute of Physics 0-7354-0098-9/02/$19.00, Pages 231-236.
6) VLADISLAV CAPEK and DANIEL SHEEHAN, “Challenges to the Second Law of Thermodynamics,” Springer, 2005, in particular pages 202-206.
7) US Patent Application by Roderich Graeff, titled “Gravity Induced Temperature Difference Device.”
8) BOREYKO ET AL., “Planar jumping-drop thermal diodes,” Applied Physics Letters 99, 234105 (2011).
9) RODERICH W. GRAEFF, “Measuring the Temperature Distribution in Gas Columns”, CP643, Quantum Limits to the Second Law: First International Conference, Edited by D. P. Sheehan, 2002 American Institute of Physics 0-7354-0098-9/02/$19.00, Pages 225-230.
10) CHUA-HUA CHEN, “Jumping Droplets Take a Lot of Heat, as Long as It Comes in a Cool Way, Science Daily 2011/12.

### BACKGROUND

The adiabatic temperature gradient in the atmosphere produced by the Earth's gravitational field has been suggested by Joseph Loschmidt, a nineteenth century physicist, as a means for generating energy (Reference 4).

In US Patent application 20030145883, Graeff repeats Loschmidt's ideas of extracting energy from a gravity-induced temperature gradient. However, Graeff's disclosure is unworkable for several reasons. His gravity machine is impractical because of its size. Furthermore he ignores parasitic thermal shorts caused by his supporting structure that carries particle species not affected by gravity. His disclosure is also limited to those implementations mediated by gravity and ignores other possible mediating forces such as the electrical field or the van der Waals force. In addition, Graeff fails to propose any explanation for reconciling prevalent scientific beliefs with Loschmidt's thought experiment.

No one has successfully and unequivocally demonstrated the validity of Loschmidt's idea. No one has successfully and unequivocally demonstrated the validity of the analogy between Loschmidt's ideas and vapor/liquid interfaces and gas adsorbed on surfaces (Reference 5 and Reference 6 pages 202-207). No one has shown a clear understanding of the thermal flow issues involved in successful implementations. No one has described analogs of the atmospheric adiabatic temperature gradient making use of hydrophobic and hydrophilic surfaces or semiconductors. No one has produced an enabling description of a working model of Loschmidt's idea. This patent disclosure does.

Further features, aspects, and advantages of the present invention over the prior art will be more fully understood when considered with respect to the following detailed description and claims.

### SUMMARY OF THE INVENTION

This invention uses adiabatic temperature profiles naturally generated when gas or gas-like particles are subjected to a potential energy gradient such as gravity, an electric field, van der Waals force, a liquid/vapor interface, a chemical gradient, or an osmotic gradient. These adiabatic profiles are most pronounced in the absence of thermal short circuits caused by heat carriers unaffected by the potential energy gradient such as photons, phonons, or gas or vapor impurity particles unaffected of less affected by the potential gradient. One of the aspects of the invention is in the selection of materials and architecture for the reduction of such short circuits.

Implementations of this invention include devices that utilize a temperature difference across a semiconductor material when a force field such as an electrical field is applied between these two points. It can also include devices that utilize such a temperature difference between the liquid phase and the vapor phase of a fluid or between an adsorbing surface and an adsorbate gas. I can also include devices that utilize a vapor phase of a liquid in contact with hydrophilic/hydrophobic surfaces when no liquid or very little liquid is actually present. Thermal short circuits in such vapor or gas devices are caused in part by the presence of parasitic impurities, vapor or gas species not affected by the energy gradient or force field, and can be reduced by the elimination of such species. Implementations also include devices that produce a temperature difference between two immiscible liquids carrying a common ion species.

One aspect of this invention allows heat to be transferred from a cold region to a hot region using the well known adiabatic lapse phenomenon. The invention comprises a force field (or potential energy) generator that creates a potential energy gradient in a given volume. This potential energy gradient could be, for example, a gravitational potential, a centrifugal force, an electrical potential, the heat of vaporization of a liquid, or the van der Waals force. The invention also requires that particles be in a gas phase or vapor phase or equivalent (e.g., charge carriers in semiconductor with a high Z factor), be constrained in the given volume and be subjected to the potential energy gradient (or force field). The particles then acquire, in part because of the adiabatic lapse, a non-uniform temperature distribution, in other words, a cold region and a hot region. Examples of such particles include gas molecules contained in the given volume or electrical carriers contained in a slab of semiconductor.

The temperature difference between the cold region and the hot region is the result of two countercurrent heat flows. The first heat transfer happens by diffusion through the particles subjected to the energy gradient. Paradoxically it occurs from the cold region to the hot region and tends to increase the temperature difference between these two regions. This heat flow, caused by the adiabatic lapse, is essentially a thermo-motive force. The magnitude of this heat flow is a function of the thermal conductivity of the gas or vapor phase and the magnitude of the force field.

A more conventional second heat transfer exists that operates as a parasitic thermal short. It conducts heat from the hot region to the cold region and tends to reduce the temperature difference between the cold region and the hot region. It is caused by agents such as photons and phonons and particles not subjected to the potential energy gradient, which travel through the device's associated or supporting structure (henceforth called supporting structure). This heat flow is, therefore, a function of the thermal conductivity of this structure. When the particles are electrons or holes, the supporting structure is the semiconductor lattice holding the carriers. When the particles are gas or vapor molecules, the supporting structure includes the walls of the container holding the gas or vapor, seals or gaskets, and, possibly, spacers keeping the walls separated from each other. In combination, these two heat transfers produce the net temperature difference between the cold region and the hot region.

Whereas the first heat flow increases the temperature difference between the hot region and the cold region, the second heat flow decreases it. The recognition of these two effects, and the implementation of measures specifically designed to maximize the first effect and reduce or eliminate the second one, forms an important aspect of this invention. Such measures include material selection and geometrical design.

An important design guideline is the ratio of the gas phase's thermal conductivity and the supporting structure's thermal conductivity. Selection of a high ratio tends to increase the temperature difference generated by the device. A good design strategy is to maximize the heat conductivity of the particles and minimize the heat conductivity of the supporting structure by choice of material and by geometry.

Another good design strategy is to maximize the heat conductivity of the energy generating device in relation to the heat conductivity of the load, thereby maximizing heat transfer to the load. Again, this can be done by maximizing the heat conductivity of the gas phase (which can be an adsorbate gas in contact with an adsorber, a vapor in contact with hydrophilic/hydrophobic surfaces or charge carriers in a thermoelectric material).

The energy generator can take several forms. The potential energy gradient can be produced by an electrical field and the particles can be electrons or holes behaving as a gas in a semiconductor slab. The gas phase's thermal conductivity is the thermal conductivity of the electrons or holes. The supporting structure is the slab of semiconductor material and the supporting structure's thermal conductivity is mediated by phonons or photons in the slab and not by the electrons or holes.

When this effect is observed in thermoelectric materials, the temperature difference is generated in the absence of electrical current, but it requires an electric field in the material. This is a new thermoelectric effect, different from the well known Seebeck, Peltier and Thomson effects and has important ramifications in the field of thermoelectricity. A new coefficient is presented to evaluate how well thermoelectric materials perform with this newly discovered effect.

The potential energy gradient can be produced as a built-in potential by a doping gradient, an n+/n type, p+/p type or Schottky junction in the slab. Alternatively the energy gradient can be produced by an electrical field externally applied to the semiconductor slab by means of insulated electrodes located outside the slab. In other words, the material can be insulated and placed between two plates of a capacitor. One should note that no direct current needs to flow through the slab. The presence of an electrical field is sufficient.

By embedding the device in the wall of an enclosure, the enclosure can operate as a refrigerator or as a heater depending on the direction of the heat flow. When an external voltage is used to control the heat flow, the enclosure can be switched from a refrigerator to a heater simply by reversing the polarity of the voltage.

The device can also be configured to produce a temperature difference across a thermoelectric device (Seebeck device) thereby converting heat to electricity.

The temperature difference can also be used to generate hot carriers in a semiconductor slab, such that the hot carriers generate photons. The photons can then be utilized as such or can be captured by a photovoltaic device to produce electricity.

The particles used by the device can also be in the form of molecules of a vapor above the surface of a liquid. In this variation, the potential energy gradient is caused by the heat of vaporization of the liquid. The supporting structure is the container made of a solid material holding the vapor and the liquid. The gas phase's thermal conductivity corresponds to the thermal conductivity of the vapor. The supporting structure's thermal conductivity is the conductivity caused in part by phonons travelling in the solid material of the container, including the wall and, possibly, spacers separating the walls; in part by photons being exchanged between the walls; and in part by non-vapor molecules mixed with the vapor but not affected by the heat of vaporization. The cold region corresponds to the walls of the container in contact with the vapor and the hot region, to the walls in contact with the liquid.

Yet another variation makes use of a vapor/liquid system in which a first set of walls has a hydrophilic surface in contact with the liquid and a second set of walls has a hydrophobic surface in contact with the vapor. The liquid is selected to be affected by the hydrophilic surface and the hydrophobic surface. A design strategy is to use a vapor with a high thermal conductivity (e.g., low molecular weight) operating within a narrow gap between the hydrophobic surface and the hydrophilic surface. The gap can be as narrow as the mechanical limitations allow except that a gap essentially smaller than the mean free path of the vapor molecules does not offer any substantial increase in heat conductivity. Spacers with a size in the order of microns or even sub microns can be used to keep the surfaces apart. Alternatively to spacers, microlithography (for around 10 microns) and nanolithography (around 100 nanometers) sometimes called photolithography, can be used to fabricate separating structures. Depending on the range of temperature desired, vapors of water, ammonia or methane could be employed. Other well known refrigerant gases could also be utilized.

In conjunction with, or independently of, the hydrophobic surface and hydrophilic surface, the liquid can be made to carry a salt in solution. This approach has the advantage of enhancing the transfer of vapor molecules to the liquid by increasing the heat of vaporization of the liquid. In addition, should a drop of pure liquid condensate on the cold (hydrophobic) wall this drop will have the tendency to evaporate and the vapor to return to the salt-spiked liquid.

Yet another variation makes use of the adsorption of gases on certain surfaces. According to this variation, the particles are molecules of an adsorbate gas above an adsorbing surface and the potential energy gradient is caused by van der Waals force at the adsorbing surface. The supporting structure is a container holding the adsorbate gas. A first set of walls of the container are configured as adsorbers and a second set of walls are configured as non-adsorbers. The supporting structure's thermal conductivity is mediated in part by phonons travelling in the walls of the container and, possibly, in spacers separating the walls, in part by photons being exchanged between the walls, and in part by non-adsorbate gas molecules mixed with the adsorbate gas molecules but not affected by the van der Waals force. The cold region corresponds to the non-adsorber walls and the hot region, to the adsorber walls. One should note that, when no liquid is present, the vapor implementation described above becomes identical to the gas version. The hydrophilic surface then corresponds to the adsorbent surface, and the hydrophobic surface to the non-adsorbent surface.

Multilayer devices can be built in layers allowing them to be thermally connected in series, such that temperature differences produced by the layers add up. These devices can be built singly, in stacks or in rolls.

These multilayer devices can be applied to the wall of a heater or cooler or can be wrapped in a box-like shape to produce a cooler or a heater. They can also be formed from a single sheet or two sheets wrapped with an insulation mesh or spacers in the spiral to separate each spiral turn. The implementations also include stacks of adiabatic thermal generators (thermally connected in series) with Seebeck devices (thermally connected in series but electrically connected in parallel).

Yet another application utilizes the adiabatic temperature distribution of at least one electron or hole in a polar molecule. The electron or hole is in the conduction band of, but confined to, the polar molecule. The potential energy gradient is caused by the electric field generated by the polar molecule. The gas phase's thermal conductivity corresponds to the thermal conductivity of the electron or hole. The supporting structure is the polar molecule itself. The thermal conductivity of the supporting structure is the component of the thermal conductivity between the two polar ends, which is not caused by the electron or hole. This conductivity may be caused by phonons or photons traveling between the two ends of the molecule or by agents outside the molecules (e.g., other molecules). The cold region is the polar end that repels the electron or hole, and the hot region is the polar end that attracts the electron or hole.

Applications of this technology include refrigerators, heaters and electrical generators. Power supplies and coolers can be fabricated as integral subcomponents of semiconductor chips or of semiconductor modules, each module comprising several chips.

The basic concept of this invention is not limited to the examples described herein but also includes other situations in which particles moving with at least one degree of freedom, acquire an adiabatic temperature distribution as the result of a force field or potential energy gradient. These include, for example, electrons moving within a polar molecule, for example a liquid crystal.

An object of this invention is therefore an energy generator capable of transferring heat across a volume from a cold region to a hot region and comprising:
a. particles in a gas phase;
b. a supporting structure restraining the particles to the volume;
c. a force field producing a gradient in potential energy in the volume, the particles being subjected to the force field and, consequently, developing a non-uniform distribution in temperature resulting in a temperature difference between the cold region and the hot region;
d. the gas phase having a gas phase's thermal conductivity;
e. the supporting structure having a supporting structure's thermal conductivity; and
f. ratio of the gas phase's thermal conductivity to the supporting structure's thermal conductivity being selected to be sufficiently high to produce the temperature difference.

It is also an object for the energy generator to comprise:
a. a first heat transfer occurring by diffusion through the gas phase from the cold region to the hot region, in accordance with the thermal conductivity of the gas phase, the first heat transfer being a result of an effect dubbed thermo-motive force caused by the force field and the first heat transfer contributing to increasing the temperature difference between the cold region and the hot region;
b. a second heat transfer also called thermal short circuit, occurring from the hot region to the cold region, the second heat transfer being a function of the supporting structure's thermal conductivity, the second heat transfer contributing to reducing the temperature difference between the cold region and the hot region; and
c. the combination of the first heat transfer and the second heat transfer resulting in the temperature difference between the cold region and the hot region.

It is also an object for the energy generator for the force field to be an electrical field, and for the particles to be electrons or holes behaving as a gas in a semiconductor slab, the gas phase's thermal conductivity being the thermal conductivity of the electrons or holes, the supporting structure being the slab of semiconductor material and the supporting structure's thermal conductivity being mediated by phonons in the slab.

It is also an object for the energy generator to comprise an electrical field produced by a doping gradient or junction in the slab.

It is also an object for the energy generator to comprise a doping gradient or junction comprising a material of the n+/n type or of the p+/p type.

It is also an object for the energy generator to comprise an electrical field produced by electrodes external to the slab, the electrons or holes being constrained by electrical insulation not to flow as a direct current through the slab.

It is also an object for the energy generator to comprise a slab comprising a quantum well material.

It is also an object for the energy generator to comprise a temperature difference generating hot carriers in the slab, the hot carriers generating photons.

It is also an object for the energy generator to comprise a photovoltaic device, wherein the temperature difference generates hot carriers in the slab, the hot carriers generating photons, the photons being captured by the photovoltaic device thereby generating electricity.

It is also an object for the energy generator to comprise:
a. particles are molecules of a vapor above the surface of a liquid corresponding to the vapor;
b. a potential energy gradient caused by the heat of vaporization of the liquid;
c. the gas phase's thermal conductivity being the thermal conductivity of the vapor;
d. a supporting structure including a container made of a solid material, holding the vapor and the liquid;
e. the supporting structure's thermal conductivity possibly being mediated by phonons travelling in the solid material of the container;
f. the supporting structure's thermal conductivity possibly being mediated by photons being exchanged between the walls;
g. the supporting structure's thermal conductivity possibly being mediated by other molecules different from and mixed with the vapor molecules, and
unaffected by the heat of vaporization; and
h. a cold region being a first set of walls of the container in contact with the vapor and a hot region being a second set of walls of the container in contact with the liquid.

It is also an object for the energy generator to comprise a first set of walls having a hydrophilic surface in contact with the liquid and the second set of walls having a hydrophobic surface in contact with the vapor, the liquid selected to be affected by the hydrophilic surface and the hydrophobic surface.

It is also an object for the energy generator to comprise a liquid carrying a salt as a solute.

It is also an object for the energy generator to comprise:
a. particles being molecules of an adsorbate gas above an adsorbing surface;
b. a potential energy gradient caused by van der Waals force at the adsorbing surface acting on the adsorbate gas;
c. a gas phase's thermal conductivity being the thermal conductivity of the adsorbate gas;
d. a supporting structure including a container made of a solid material, holding the adsorbate gas, a first set of the walls of the container configured as adsorber walls for the adsorbate gas and a second set of walls configured as non-adsorber walls for the adsorbate gas;
e. a supporting structure's thermal conductivity possibly being mediated by phonons travelling in the solid material of the container,
f. a supporting structure's thermal conductivity possibly being mediated by photons being exchanged between said walls of said container,
g. a supporting structure's thermal conductivity possibly being mediated by non-adsorbate gas molecules mixed with the adsorbate gas molecules but not affected by the van der Waals force; and
h. a cold region being the non-adsorber walls and hot region being the adsorber walls.

It is also an object for the energy generator to comprise:
a. an adsorbate gas being hydrogen;
b. an adsorbing surface having adsorbing sites, the adsorbing sites not more than 25% bound to atoms of the hydrogen;
c. adsorber walls being separated from non-adsorber walls by no more than 1 millimeter.

It is also an object for the energy generator to comprise adsorber walls separated from non-adsorber walls by no more than 1 micron.

It is also an object for the energy generator to comprise:
a. at least one particle, being at least one electron or hole and confined to a polar molecule, the particle in a conduction band of the polar molecule, the polar molecule having two polar ends;
b. a potential energy gradient being caused by an electric field generated by the polar molecule;
c. a gas phase's thermal conductivity being the thermal conductivity of at least one electron or hole;
d. a supporting structure including the polar molecule;
e. the supporting structure's thermal conductivity being the thermal conductivity between the polar ends, not caused by at least one electron; and
f. a cold region being one of the polar ends that repels the electron or hole, and a hot region being one of the polar ends that attracts the electron or hole.

It is also an object for the energy generator for the ratio of the gas phase's thermal conductivity to the supporting structure's thermal conductivity to be greater than 5.

It is also an object for the energy generator to be configured to produce the temperature difference with the cold region located inside of a refrigerator and the hot region located outside of the refrigerator.

It is also an object for the energy generator to be configured to produce the temperature difference with the hot region located inside of a heater and the cold region located outside of the heater.

It is also an object for the energy generator to be configured to produce the temperature difference across a thermoelectric device thereby converting heat to electricity.

It is also an object for the energy generator to have a supporting structure comprising two parallel plates, at least one of the plates being configured with protuberances, the protuberances acting as spacers when the plates are assembled in a sandwich.

It is also an object for the energy generator to have a supporting structure comprising two parallel plates, at least one of the plates being configured with grooves, the grooves facilitating fluid flow.

### BRIEF DESCRIPTION OF THE DRAWINGS

FIG. 1 illustrates one of the requirements of the adiabatic process: a potential energy gradient.

FIG. 2 illustrates a thought experiment showing heat flow from a cold region to a hot region when the adiabatic temperature profile in a gas subjected to a gravitational field, is thermally disturbed.

FIG. 3 shows how a heat engine can be connected between the hot region and the cold region in gas column that has developed an adiabatic temperature gradient as a result of a force field.

FIG. 4 shows how the operation of the system is a function of the thermo-motive force, the series thermal conductivity of the electrical carriers Kₛ, the parallel thermal conductivity of the phonons Kₚ in the material lattice, and the thermal conductivity of the load, K_{L}.

FIG. 5 shows a simple one-stage implementation of an adiabatic thermal generator making use of an n+/n junction.

FIG. 5A shows a simple one-stage implementation of an adiabatic thermal generator making use of a p+/p junction.

FIG. 5B shows a simple one-stage implementation of an adiabatic thermal generator making use of a Schottky junction.

FIG. 5C shows a simple one-stage implementation of an adiabatic thermal generator making use of an external field produced by electrode plates on either side of an electrically insulated thermoelectric material.

FIG. 6 shows a multilayer device with alternating n+/n and p+/p junctions.

FIG. 7 shows a multilayer device with alternating layers of p-type material; electrical insulating, thermally conductive layer; electrode; electrical insulating, thermally conductive layer; n-type material; electrical insulating, thermally conductive layer. The electrodes produce an electrical field across the thermoelectric material.

FIG. 8 shows how a built-in potential can be supplemented by means of an externally applied electric field in a stack of Schottky junctions.

FIG. 9 illustrates how the layers can be shaped as an enclosure, for the purpose of making a heater or a cooler.

FIG. 10 shows how organic or thin film material can be mounted on a flexible substrate such as Mylar™

FIG. 10A shows how organic or thin film material can be fabricated in a roll.

FIG. 11 shows a simple electrical generator comprising an adiabatic thermal generator and a Seebeck device. Both devices have identical type material.

FIG. 12 shows a simple electrical generator comprising an adiabatic thermal generator and a Seebeck device. Each device has a different type material.

FIG. 13 shows two devices back-to-back, each one operating as an adiabatic thermal generator and as a Seebeck device.

FIG. 14 shows a multilayer electrical generator, each layer operating as an adiabatic thermal generator and as a Seebeck device. In this implementation the electrical field is perpendicular to the plane of the stack and these layers have graded doping and they alternate according to the LnH/LpH pattern. (i.e., (Low n-doping−High n-doping/Low p doping−High p doping.) The current must go back and forth between the layers and necessitates additional wiring or an appropriate construction.

FIG. 15 shows a realistic implementation of the LnH/LpH configuration of the device in FIG. 13 and comprises a structure that allows the current to flow back and forth between layers.

FIG. 16 shows a second realistic implementation of the LnH/LpH configuration comprising a structure to invert the current flow. This structure can be assembled by stacking the parts.

FIG. 17 shows a configuration in which the doping gradient is parallel to the semiconducting layers and these layers have graded doping and they alternate according to the LnH/HpL pattern. (i.e., (Low n-doping−High n-doping/High p doping−Low p doping.)

FIG. 18 illustrates how the device shown in FIG. 16 can be chained in series to increase the output voltage.

FIG. 19 shows how the device of FIG. 6 can be thermally connected to a cold sink and to a heat sink through a thermoelectric generator to generate electricity.

FIG. 20 shows how a conventional checkerboard array thermoelectric generator can be modified by replacing some of its array elements by one or several adiabatic thermal generators.

FIG. 21 shows how an adiabatic thermal generator can be placed in a sandwich between two thermoelectric generators.

FIG. 22 illustrates how a thermoelectric generator can be placed in a sandwich between two adiabatic thermal generators.

FIG. 23 shows how two thermal generators and two thermoelectric generators can be thermally connected end-to-end thereby forming a rectangle.

FIG. 24 illustrates in perspective view how two adiabatic thermal generators each one wrapped in a roll can be positioned on either side of a Seebeck device.

FIG. 24A shows in front view how two adiabatic thermal generators each one wrapped in a roll can be positioned on either side of a Seebeck device.

FIG. 24B illustrates an array of devices depicted in FIGS. 24 and 24A.

FIG. 25 illustrates how the adiabatic device generates heat phonons which are used by a Seebeck device to generate electricity.

FIG. 25A illustrates how the adiabatic device generates heat photons which are used by a photovoltaic device to generate electricity.

FIG. 26 illustrates a device in which hot carriers are generated by means of an adiabatic process induced by two transparent electrodes on either side of an insulated semiconductor slab.

FIG. 26A illustrates a device in which hot carriers are generated by means of an adiabatic process induced by two electrodes on either side of an insulated semiconductor slab, one electrode being transparent and the other being a mirror.

FIG. 27 provides a possible architecture showing how a photovoltaic device can be coupled to an adiabatic light generating device, to generate electricity.

FIG. 28 shows a simple one-layer adiabatic thermal generator making use of a vapor liquid interface.

FIG. 28A shows a multi-layer adiabatic thermal generator making use of a vapor liquid interface.

FIG. 29 shows the device of FIG. 28 wrapped into a roll.

FIG. 29A shows the device of FIG. 28A wrapped into a multilayer roll.

FIG. 29B illustrates how the device's parallel plates can be configured as the fins of a heat sink or of a cold sink.

FIG. 29C shows two surfaces in a hydrophobic/hydrophilic implementation or in an adsorbing/non-adsorbing implementation. At least one surface is configured with small protuberances that act as spacers.

FIG. 29D illustrates two surfaces in a hydrophobic/hydrophilic implementation or in an adsorbing/non-adsorbing implementation. At least one surface is configured with grooves to facilitate fluid flow during evacuation or gas/vapor loading.

FIG. 30 shows a simple one-layer adiabatic thermal generator making use of adsorption between a gas and a surface.

FIG. 30A shows a multi-layer adiabatic thermal generator making use of adsorption between a gas and a surface.

FIG. 31 shows a two thermal generator back to back in antiparallel fashion and connected at their ends through Seebeck junction.

FIG. 32 shows a hexagonal configuration of three thermal generators and three Seebeck junctions. The cold sinks are connected to the cold regions to extract heat from the environment.

FIG. 33 also shows a hexagonal configuration of three thermal generators and three Seebeck junctions. The cold sinks are connected to the hot regions to extract heat from the environment and lower the temperature of the assembly.

FIG. 34 illustrates a hexagonal configuration of three thermal generators and three Seebeck junctions. The cold sinks are connected to the hot regions to extract heat from the environment and lower the temperature of the assembly. Additional Seebeck junctions are connected in series between the environment and the cold regions.

FIG. 35 illustrates a polar molecule wherein a conduction band electron has an adiabatic distribution.

### DETAILED DESCRIPTION

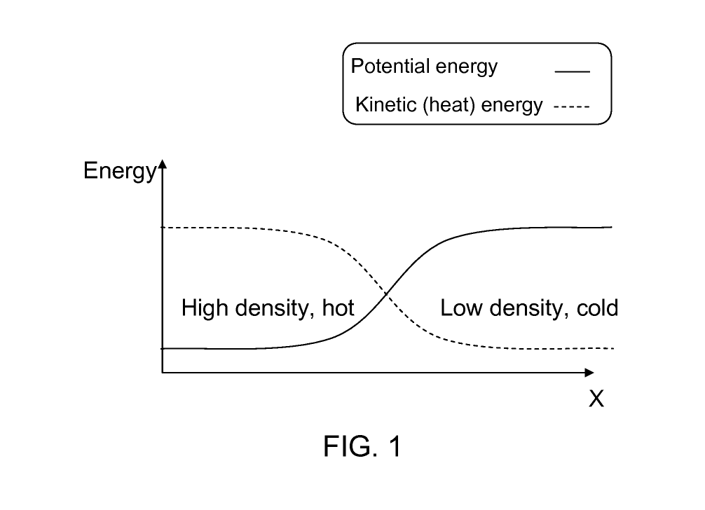

In the presence of a potential energy gradient such as shown in FIG. 1, gas molecules have the natural tendency to acquire an adiabatic profile across the gradient, with the hotter ones compressed downstream (at the bottom) and the colder ones expanded upstream (at the top). Essentially, gas molecules which diffuse up the gradient convert their kinetic energy into potential energy. The reverse happens when gas molecules diffuse down the gradient. The average total energy for each gas molecule is uniformly distributed. This phenomenon occurs naturally without any external agency and corresponds to a state of thermodynamic equilibrium, maximum entropy and uniform enthalpy.

This phenomenon, well known in the fields of meteorology and aviation, is called the atmospheric lapse when it occurs in the atmosphere, but may also happen in different circumstances for example when charged particles are subjected to an electrical field. For the purpose of this explanation we shall consider air molecules subjected to gravity.

When the gas is perturbed, for example by injecting or absorbing heat anywhere along the gradient, this heat is redistributed in the gas such as to restore the adiabatic profile, thus reestablishing the state of maximum entropy and uniform enthalpy of the gas. This heat flow is not forced. It happens naturally as a direct consequence of the generalized formulation of the Second Law of Thermodynamics to be discussed below. It is also a consequence of the equipartition principle and of the virial theorem.

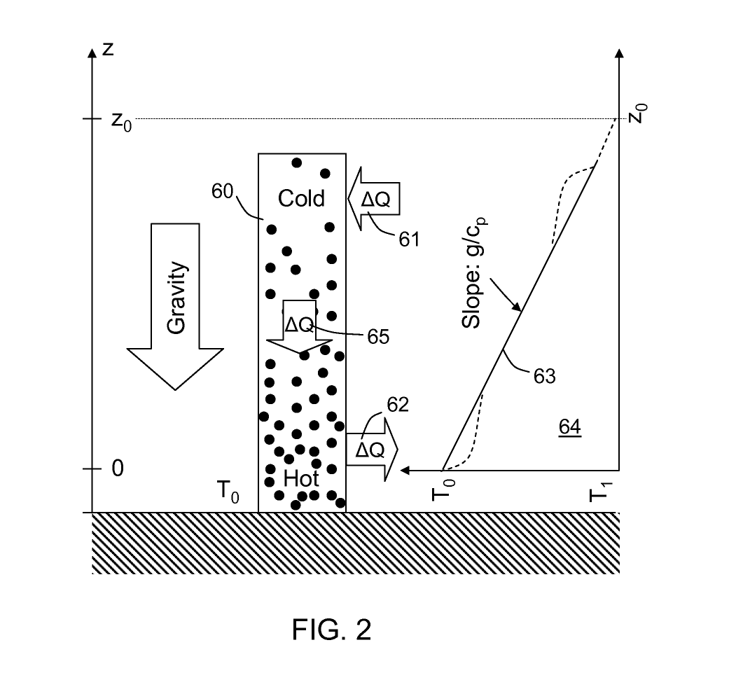

The following thought experiment illustrated in FIG. 2 is illustrative: a gas column 60 in a gravity field has reached adiabatic equilibrium such that a temperature gradient 63 (shown in the graph 64) develops along the column 60, the top of the column being colder than its bottom. A certain amount of heat AQ is injected 61 in the cold region at the top, and the same amount of heat AQ 62 is removed from the hot region at the bottom. If, henceforth left undisturbed, the system must then return to its original temperature profile (i.e., the state of maximum entropy). To do so, the heat injected at the top must flow downward 65. Paradoxically this heat flow occurs from cold to hot and therefore violates Clausius' formulation of the Second Law which asserts that heat can never flow up a temperature gradient, in other words, from cold to hot. Fortunately, the paradox can be resolved by recognizing that his formulation applies only to systems devoid of force fields (e.g., inertial systems for particles with mass or environments devoid of electrical field for particles with charge) and associated adiabatic temperature lapses. Clausius formulation can be salvaged by generalizing it: in the absence of a force field his statement remains intact. In the presence of a force field, heat always flows down a relative temperature gradient where the temperature gradient is defined as relative to a temperature distribution adiabatically generated under the influence of the force field.

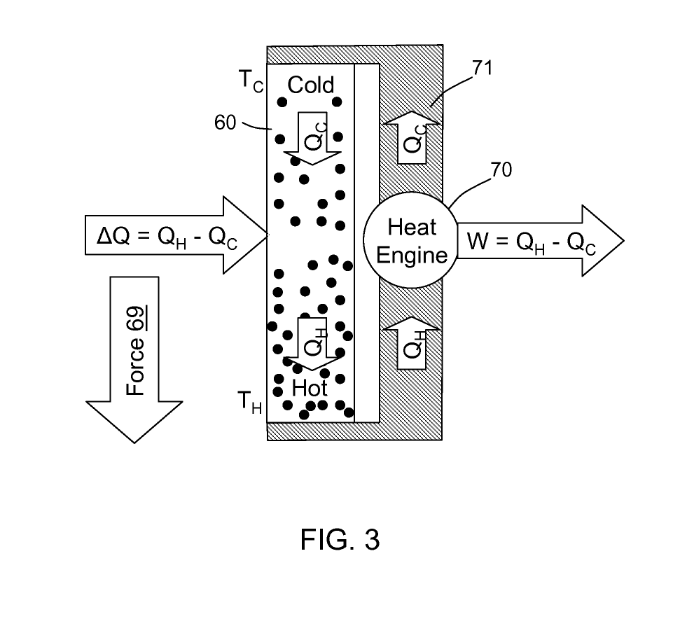

FIG. 3 illustrates how energy can be extracted from a temperature gradient adiabatically induced in particles 60 by a force field 69. A heat engine 70 is connected between the hot region and the cold region by means of a heat conductor 71 unaffected by the force field. Instances of such heat conductors include solid materials carrying heat phonons or empty space carrying heat photons. These phonons and photons are classically unaffected by either gravity or the electrical field. Such heat conductors could also be implemented by particles having masses smaller than the particles 60 in the force field. These lesser-mass particles experience a lesser temperature gradient and therefore can be used to carry heat up the force field.

The heat engine operates between temperatures T_{H} and T_{C}. Heat Q_{H} is extracted from the hot region and heat Q_{C} is dumped in the cold region. Since the thermodynamic equilibrium of the gas is disturbed, heat flows from the cold region to the hot region to restore equilibrium, as explained in the paragraph referencing FIG. 2. Work W=Q_{H}−Q_{C} is generated by the heat engine 70. Energy W is therefore extracted from the gas column. For a system operating adiabatically (no heat transfer with its environment), the temperature of the gas goes down until the particles cease to have enough energy to reach the top of the column, thereby stopping the heat flow and the operation of the device. For a system operating isothermally (no internal change in temperature), the energy removed as work W is replenished as ΔQ=Q_{H}−Q_{C}, (First Law) thereby converting heat AQ from the environment to work W.

An adiabatic temperature gradient in a gas subjected to a force field depends on the interaction of the particles with the field. As particles go up in the gradient, they convert their kinetic energy to potential energy and therefore lower their temperature, and vice versa, when they go down, they increase their temperature. This effect is beneficial to the energy generation process as it tends to maximize the temperature difference between different regions along the energy gradient. A second effect however is detrimental: heat carried by photons, phonons or molecules unaffected by, or insensitive to, the energy gradient, tends to produce a thermal short between different regions along the energy gradient. Thus, to maximize performance, heat flow due to field sensitive particles should be maximized and heat flow caused by field insensitive mechanisms (e.g. photons, phonons, lighter particles) should be minimized. These two thermal flows determine in part the performance of the invention in generating energy and are well known in thermoelectricity in contributing to the Z factor—a coefficient used to evaluate the performance of thermoelectric materials. This topic shall be discussed in greater detail in the section on thermoelectric materials but is also applicable to all other implementations not using thermoelectric materials.

TABLE 1

| | Gas | Thermo- | Liquid/ | Adsorb- | |
|---|---|---|---|---|---|
| | Columns | electric | Vapor | ing | Polar |
| | (Loschmidt) | Material | interface | Surface | molecule |
| Potential | Gravity | Electric | Heat of | van der | Electric |
| Gradient | | Field | Vaporiza- | Waals | Field |
| | | | tion | Force | |
| Particles | Gas | Electrons/ | Liquid/ | Gas | Electrons |
| | molecules | holes | Vapor | molecules | |
| | | | molecules | | |

Table 1 lists some situations in which an adiabatic profile occurs in gas or “gas-like” particles occupying a space traversed by a potential energy gradient. The theme is always identical but the actors are different. The energy gradient can be instantiated by gravity, an electric field, van der Waals force, heat of vaporization/condensation, osmotic pressure, centrifugal force, etc. Particles can be molecules, electrons ions, etc. Clearly the table is not exhaustive since many more such energy gradients can occur.

In summary, a useful adiabatic temperature gradient can exist in the presence of four factors: 1) a force field such as gravity (or acceleration), the electrical field, or van der Waals force; 2) particles such as molecules or electrons in a gas phase and subjected to the force field; 3) a configuration in which heat is transferred mostly by diffusion of the particles and 4) a relative absence of a thermal short circuit mediated by mechanisms affected to a lesser extent or completely unaffected by the force field. Such mechanisms could take the form of lighter molecules or uncharged particles such as phonons or photons.

Previous researchers did not address correctly heat flow issues. In his book (reference 6 page 202) Sheehan states: “Loschmidt's argument skates over many crucial thermodynamic and statistical mechanical issues, including: A) Radiation and convective heat transport, which would counter the conductive energy transport and erase the temperature gradient, are ignored. Heat transport rate is not addressed since [the temperature gradient] is derived from equilibrium consideration.

Not only Loschmidt ignores radiation and convection as mechanisms for thermal shorts, but both Loschmidt and Sheehan also ignore a most important heat conduction mechanism: the parasitic, short circuiting, heat flow caused by particles unaffected by the force (gravity or electric field) field. Such particles include phonons in a thermoelectric solid material, gas molecules (e.g., air) in a vapor/liquid system (e.g., water/water vapor) and non-adsorbed molecules (e.g., nitrogen) in adsoption systems (e.g., hydrogen/nickel).

In his book, Sheehan discusses research performed by R. W. Graeff. (Reference 6 page 204) Both he and Graeff teach away from this invention. In an effort to eliminate convection currents, Sheehan states “attempts were made to inhibit convection by loading the gas or liquid sample in a matrix of plastic fibers or glass microspheres (radius=5 μm). The volume fraction of liquid to microspheres were roughly 0.4:0.6.″

These attempts were counterproductive because the added material enhanced parasitic heat conductivity. In this invention, the parasitic heat conductivity of the supporting structure is kept at a minimum. For example in the solid state thermoelectric implementation high Z materials are selected. These materials are characterized by a low ratio of phonon conductivity to electronic conductivity. In the vapor/liquid implementation the heat conductivity of the supporting structure is minimized by selecting a volume fraction of liquid to spacers greater than 99:1. In this instance spacers are part of the supporting structure as their function is to maintain a gap between a hydrophobic plate and a hydrophilic plate. The same approach is used in the adsorption implementation.

### Use of Gravitational Gradient

An adiabatic gradient can occur when a gas column is subjected to a potential energy gradient such as a gravitational pull. The gas settles into an adiabatic profile such that the lower regions of the column are hotter than the upper regions. This phenomenon has been recognized by Joseph Loschmidt, a contemporary of Ludwig Boltzmann and James Maxwell, as a means for extracting energy from the atmosphere.

The adiabatic temperature profile in such a column is described by the well known equation:

T=T₀−(M_{gas}/C_{p gas})gh

where T is the temperature at elevation h, T₀ is the ground temperature, M_{gas} is the molecular weight of the gas, C_{p gas} is the molar heat capacity, g is the acceleration of gravity and h is the height above ground.

Different gases having different molecular weights settle in different temperature profiles. Two tall columns in a gravity field, each column containing a different gas will have, at any given height above ground, a different temperature. One of the gas columns, for example the one containing the lighter gas, could be replaced by a thermal link connecting the ground to any desired elevation where the temperature difference is to be tapped. This thermal link can be implemented in the form of a highly thermally conductive bar (copper), allowing heat phonons to travel. Alternatively, the thermal link can be in the form of an optical device directing photons between the warmer ground and the colder desired elevation. The optical device could comprise, for example, a black body at the top of the column, a black body at the bottom of the column and a tube with a highly reflective inner wall connecting the black bodies. Since phonons or photons are essentially (classically) not affected by gravity, their energy (temperature) does not change as they travel vertically and therefore can be an effective thermal link between the top and the bottom.

A heat engine connected between the columns by such a thermal link could conceivably generate energy from the temperature difference between different altitudes (several miles). Unfortunately, the large dimensions required for such a device make it unfeasible. The gravity version of this invention was discussed as a means for explaining this technology and as an introduction to more feasible versions to be discussed below.

### Use of Thermoelectric Materials

An adiabatic profile can also occur in a semiconductor, and more particularly in a thermoelectric material in which electrical carriers, electrons or holes, are subjected to an electrical field. These electrical carriers behave like gas particles in the material and therefore they can be heated when compressed and cooled when expanded.

This adiabatic phenomenon arises even in the absence of electrical current (for example in a capacitive device) and generates a temperature difference across a thermoelectric material when this material is traversed by an electrical field. This phenomenon is a new and unrecognized thermoelectric effect which can be used to generate energy and should be added to the list of well know effects such as the Seebeck effect, the Peltier effect and the Thomson effect.

The field can be created in a number of ways, for example by a doping gradient, an n+/n junction, a p+/p junction, or a Schottky junction. The field can also be externally generated, for example, by electrodes on either side of, and insulated from, the material.

Adiabatic Device Performance Coefficient

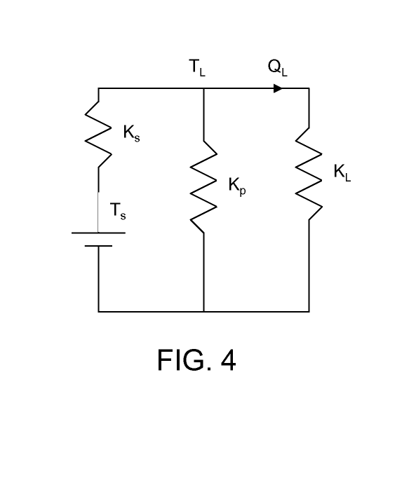

The device can be modeled by treating heat flow analogously to electrical flow as show in the FIG. 4. Assume the following:
1. Thermo-motive force Tₛ=eV/k where V is the applied voltage or the built-in voltage where k=Boltzmann constant==8.62×10⁻⁵ electron-volts/Kelvin
2. Series thermal conductivity by electrical carriers Kₛ=σLT (by Wiedemann-Franz law) where L=Lorenz number=2.44×10⁻⁸ Watts Ohms /K⁻²
3. Parallel thermal conductivity Kₚ by phonons in the material lattice.
4. Load with a thermal conductivity K_{L}.
5. Load (e.g. thermoelectric device) has efficiency η ΔT/T where ΔT/T is the Carnot coefficient

Total power input by the load:

P_{L}=T_{L}K_{L}

Total electrical power output by the load (thermoelectric device):

$$\begin{matrix}{P}_{L} = η ( {T}_{L} / T ) {T}_{L} {K}_{L} \\ = η {T}_{L}^{2} {K}_{L} / T \\ = \frac{{η ( {K}_{s} {T}_{s} )}^{2}}{{( {K}_{s} + {K}_{p} + {K}_{L} )}^{2}} \cdot \frac{{K}_{L}}{T}\end{matrix}$$

Define coefficient Λ=Kₛ/(Kₛ+Kₚ) such that:

$${P}_{L} = \frac{ηΛ {T}_{s}^{2} {K}_{L}}{T} \cdot \frac{{( {K}_{s} + {K}_{p} )}^{2}}{{( {K}_{s} + {K}_{p} + {K}_{L} )}^{2}} .$$

Where Tₛ=eV/k, Kₛ=σLT

One can calculate the maximum load power by differentiating the expression for P_{L} with respect to K_{L}, and setting dP_{L}/dK_{L}, to zero. The maximum power is achieved when the load is matched to the source.

K_{L}=Kₛ+Kₚ

With matched load the maximum power is:

$${P}_{L} = \frac{ηΛ {T}_{s}^{2} {K}_{L}}{4 T} . \\ {P}_{L} = \frac{ηΛ {e}^{2} {V}^{2} {K}_{L}}{4 {k}^{2} T} .$$

From the above equations, one can see that it is desirable for the material to exhibit a high Λ which is the thermal conductivity caused by particles affected by the adiabatic temperature profile divided by the total thermal conductivity. Ideally all heat transfer should be performed through the adiabatic process and no heat flow should occur through the supporting structure.

Many implementations are possible that use the adiabatic effect in thermoelectric materials. Some of the implementations are discussed in the examples below.

### Example 1

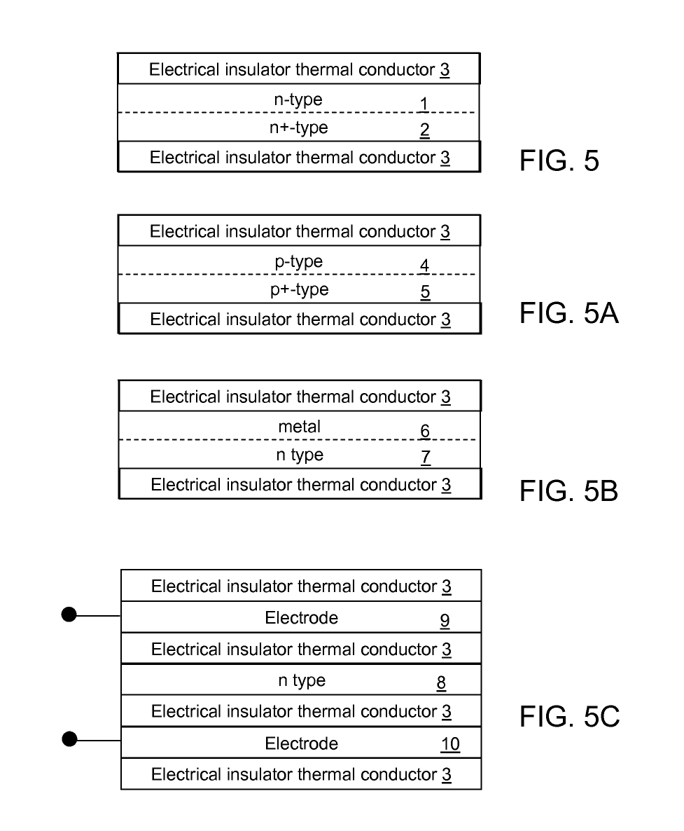

FIG. 5 illustrates a simple implementation comprising a junction between an n+/n thermoelectric material 1 and an n type material 2. The thermoelectric material is in a sandwich between two electrically insulating, thermally conductive layers 3 to allow heat flow but prevent current flow. A temperature differential develops between the two sides of the junction with the hotter region located at the bottom of the energy gradient for the material. Clearly the n+/n junction can be replaced by a p+/p junction as shown in FIG. 5A or a Schottky junction can be used as shown in FIG. 5B. Furthermore, as shown in FIG. 5C, the electric field can be generated by electrodes 9 and 10 on either side, but insulated from, an n-type 8 or a p-type thermoelectric material. The advantage of this design is that the temperature differential can be controlled and even reversed depending on the voltage applied to the electrodes. Since the electrodes are only capacitively coupled, the energy input to control the adiabatic effect is small.

### Example 2

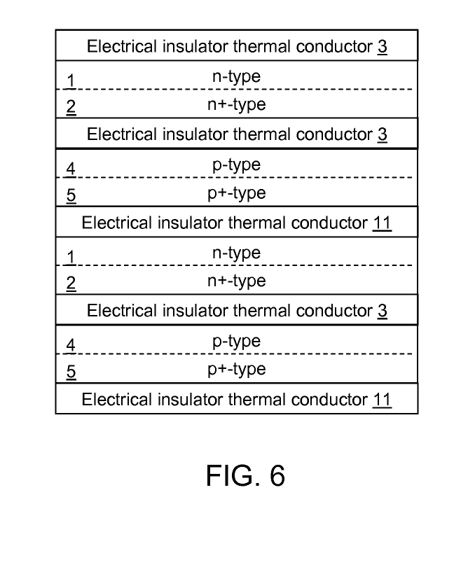

The devices shown in FIGS. 5, 5A and 5B can be stacked to generate a greater temperature difference as shown in FIG. 6. The reason for alternating n and p type material is for the built-in potential to be generated across the thermoelectric material layers rather than across the insulator separating them. Specifically, fixed positive charges are present in the n+material 2 near the insulator 3 and holes are present in the p material 4 across the insulator 3 thus cancelling or reducing the field across the insulator 3. Similarly fixed negative charges are present in the p+material 5 near the insulator 11 and electrons are present in the n material 1 across the insulator 11.

### Example 3

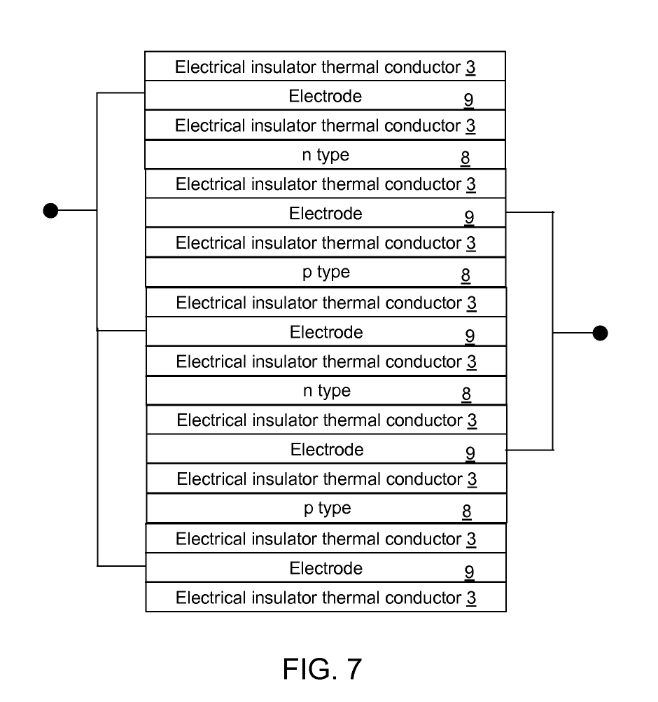

The device shown in FIG. 5C can be stacked to produce the device in FIG. 7. Electrodes are located in the stack to control or reverse the field across the thermoelectric material thereby controlling or reversing the flow of heat.

### Example 3A

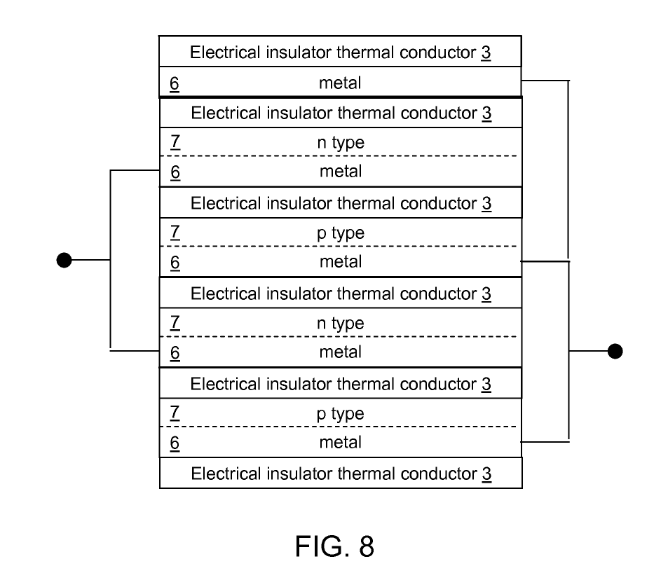

FIG. 8 shows how a built-in potential can be supplemented by means of an externally applied electric field. Slabs of semiconductor material are joined to metal layers to form Schottky junctions which are insulated and assembled in a stack. A voltage is applied to the metal layers to generate the electric field.

One should recognize that in a stack arrangement, different layers in the stack can operate at different temperatures and, therefore, for an optimum design, the design parameters for each layer may be different. Design parameters include but are not restricted to, type and amount of doping, type of semiconductor material, and the area and thickness of the device.

### Example 4

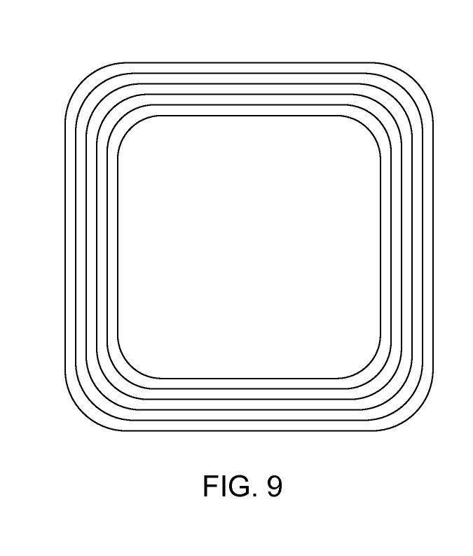

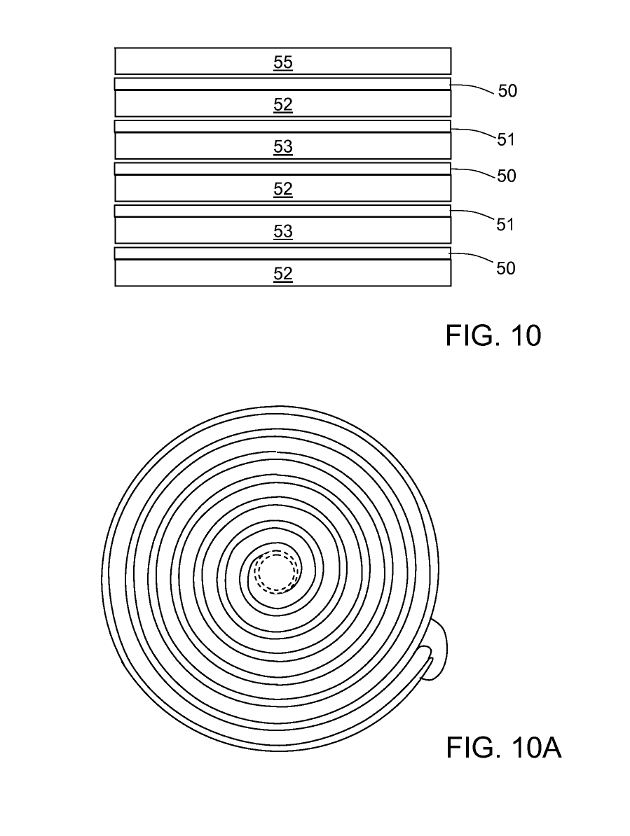

FIG. 9 shows how the devices of FIGS. 5 thru 6 can be arranged to form a container for example to make a cooler or a heater. Depending on how the layers of thermoelectric material are arranged, this container can operate as a heater or as a cooler without the need for a power input. The controllable heater or cooler system of FIGS. 4, 5 and 6 can also be configured as a container which can operate as a controllable or reversible heater/cooler. This device can be built by coating one side of a first set of Mylar™ sheets 52 with an n-type material 50 and a second set of Mylar™ sheets 53 with a p-type material 51. The two sets of sheets are then stacked such that the n-type and p-type materials alternate. The top of the stack is covered with an insulating layer 55. Electrical contact as shown in FIG. 7 can be made by dissolving the plastic on one side and along one edge of each Mylar™ sheet and orienting the edges such that all n-type sheets have their exposed edge on one side of the stack, and all p-type sheets have their edge on the other side. Contact tabs can be formed by cutting the edges in a staggered fashion like the tabs in manila folders. Alternatively to the stack architecture, two Mylar™ sheets of opposite types can be rolled together as shown in FIG. 10A. Organic and thin film thermo-electric materials are flexible and can be mounted on Mylar™ and bent or rolled.

### Example 5

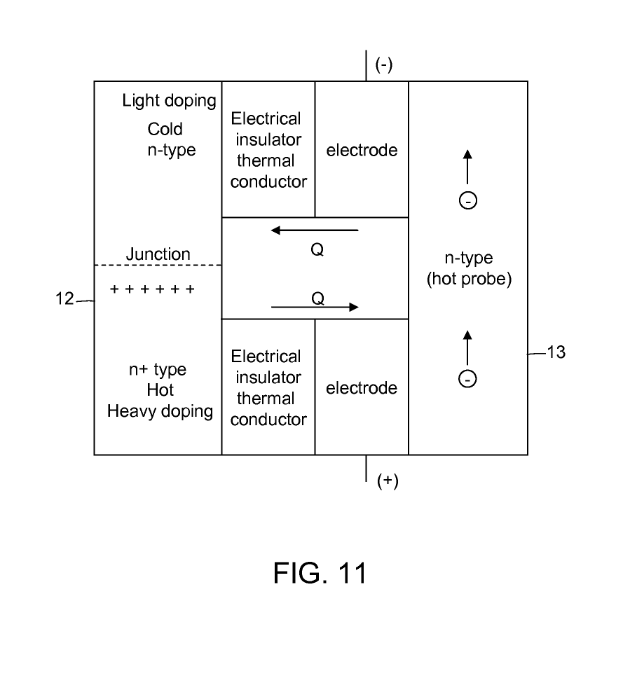

The thermoelectric device of FIGS. 5-5B can be used to generate electricity as shown in FIG. 11 by using a Seebeck thermoelectric generator. The adiabatic device 12 generates a temperature difference used by the Seebeck device 13 to generate a voltage. Obviously the Seebeck device can utilize an n type or a p type material.

### Example 6

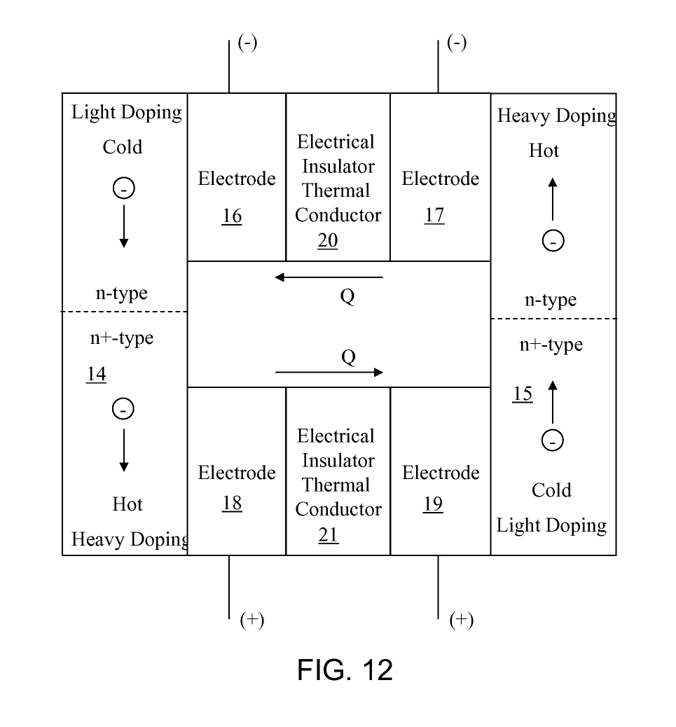

Two devices of FIGS. 5-5B can be mounted back to back as shown in FIG. 12 each one operating both as an adiabatic device and as a Seebeck device. This design makes use of the relative temperature concept. Two thermoelectric material slabs 14 and 15 with graded doping (e.g., n+/n or p+/p junction) develop a carrier temperature gradient throughout their length. Carriers are hot at the heavily doped end and cold at the lightly doped end. The slabs 14 and 15 are then placed in thermal contact with each other such that the cold end of one is placed in thermal contact with the hot end of the other. Electrodes 16, 17, 18 and 19 are placed at the points of contact and are insulated from each other by insulating layers 20 and 21.

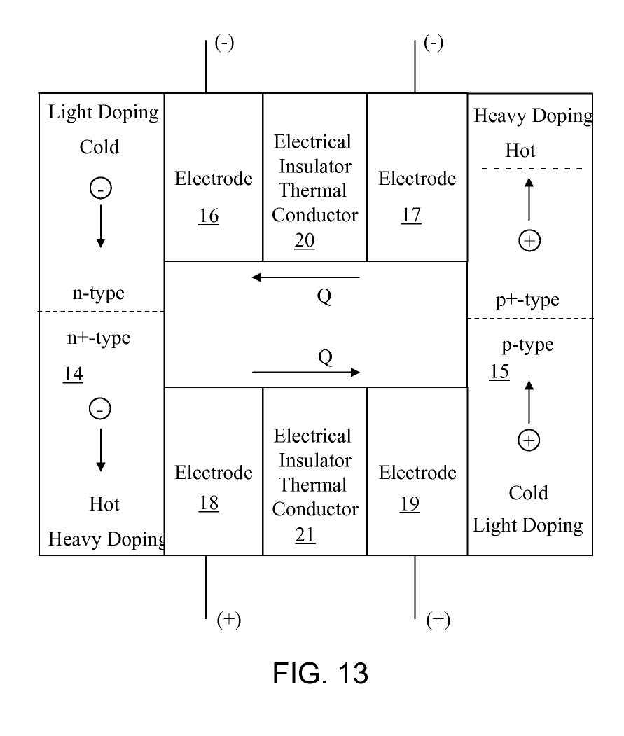

As heat flows from the hot ends of each slab to the cold ends of the other, the temperature profile of each slab deviates from its adiabatic equilibrium. The heavily doped hot end becomes relatively colder than its adiabatic profile and the lightly doped cold end becomes relatively warmer than its adiabatic profile. According to the thermoelectric effect, carriers move in the semiconductor from the (lightly doped and) relatively hot end to the (heavily doped and) relatively cold end. FIG. 12 shows a version with an n-type first semiconductor slab in thermal contact with an n-type second semiconductor slab. FIG. 13 shows a version with an n-type first semiconductor slab in thermal contact with a p-type second semiconductor slab.

### Example 7

The power output of a device can be increased by stacking adiabatic devices of the type in FIG. 13. The performance of the device in the stack can be optimized by maximizing the thermal contact between the slabs of thermoelectric material. Two design choices are available:

a. Arranging the electrical field perpendicular to the surface of the stack layers.

b. Arranging the electrical field parallel to the stack layers.

Furthermore, to achieve a good performance, the following requirements should be fulfilled if possible:
a. Good thermal contact should exist between the cold and hot ends of the layers.
b. The electrical field generated by the doping gradient (junction) should be present across the thermoelectric material because the electric field is required for the adiabatic effect to operate.
c. The current flow should ideally be in the same direction from one layer to the next. If not, the layers need to be wired to redirect the current appropriately.

Table 2 presents a few design choices that employ doping gradient or junction and wherein the electrical field is perpendicular to the slab layers. The stack configuration is expressed in the header of the table. For example the code LnH/HpL means that an n-type semiconductor with a Light to Heavy doping gradient is laid on top of a p-type semiconductor with a Heavy to Light doping gradient. This table covers n+/n and p+/p junctions but does not cover semiconductor/metal junctions and instances in which the electrical field is produced by external electrodes. Those versed in the art will understand that the table also applies to these instances since the electrical field is parallel to the doping gradient.

The doping gradient defines the direction of the electrical field within a slab. For example in the n-doped slab the field goes from the heavily doped area where the fixed charges are located, to the lightly doped area toward which electrons diffuse. The current is co-directional with carriers when the carriers are holes and counter-directional when they are electrons. The table shows that the LnH/LpH (or LpH/LnH) configuration provides good thermal contact and strong built-in potential. The current is not unidirectional between the layers and therefore needs to be redirected.

TABLE 2

| | Perpendicular Gradient | | | |
|---|---|---|---|---|
| | LnH/LnH or | LnH/HpL or | LnH/LpH or | LnH/HnL or |
| | LpH/LpH | LpH/HnL | LpH/LnH | LpH/HpL |
| Large thermal | ✓ | X | ✓ | X |
| contact area | | | | |
| Built-in poten- | X | X | ✓ | ✓ |
| tial across | | | | |
| thermoelectric | | | | |
| material | | | | |
| Current Uni- | ✓ | ✓ | X | X |
| directionality | | | | |

The built-in potential across the semiconductor is important in allowing the adiabatic separation of hot and cold carriers. In the LnH/LnH configuration some of the built-in potential is wasted since most of the voltage drop occurs across the insulator. This situation occurs because carriers in one layer migrate to the lightly doped area where they are attracted by fixed charges in the highly doped area in the next layer. This results in most of the voltage drop occurring across the insulator separating the two layers. The resulting low built-in potential across the semiconductor results in requirements for larger dimensions to achieve the same adiabatic effect. The opposite effect occurs in the LnH/LpH configuration where the carriers which diffuse toward the lightly doped area are repelled by the fixed charges in the next layer, thereby separating more efficiently the most energetic carriers from the least energetic ones and favoring the adiabatic process.

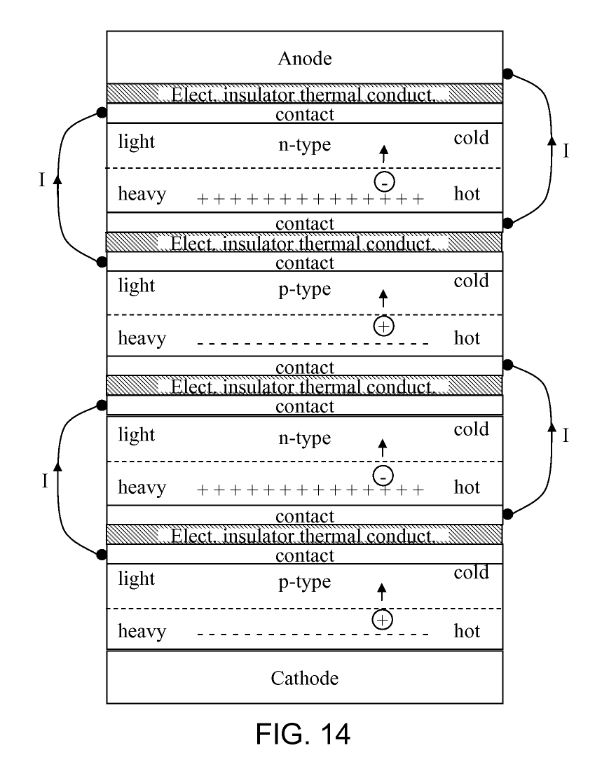

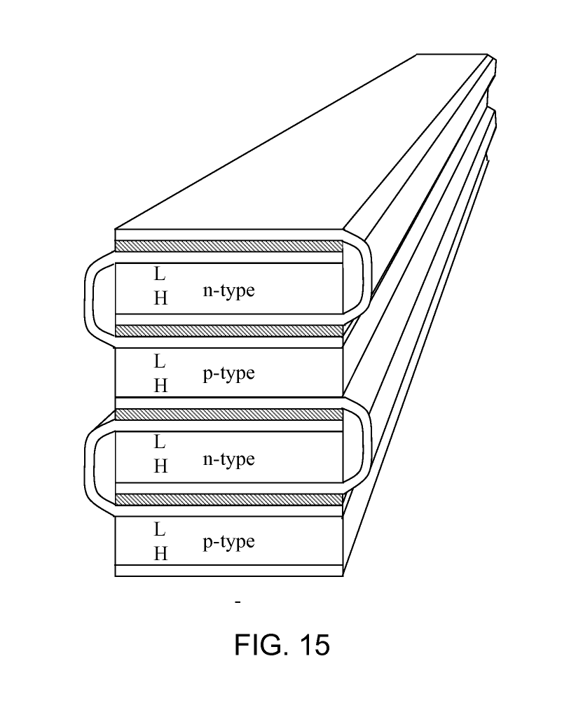

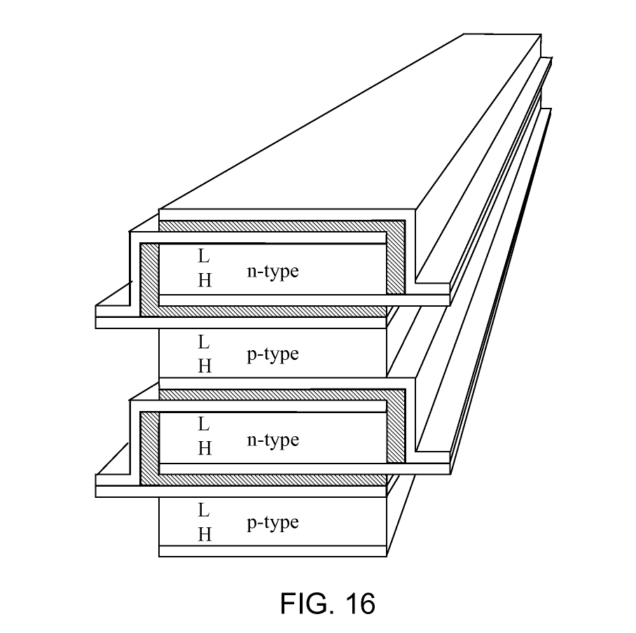

This particular configuration LnH/LpH (i.e., Low n-doping−High n-doping/Low p doping−High p doping) is illustrated in FIG. 14. The figure shows a number of units connected in series to obtain a higher voltage. As can be seen, the direction of the current in the n-type slabs is backward and therefore the connection to these slabs needs to be inverted. Three dimensional implementations are shown in FIGS. 15 and 16.

### Example 8

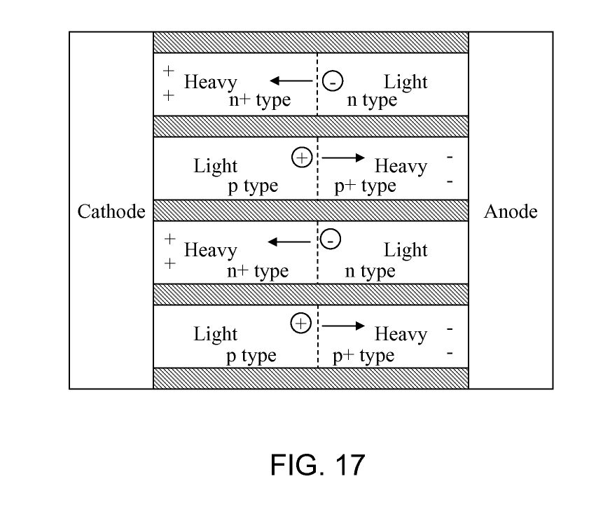

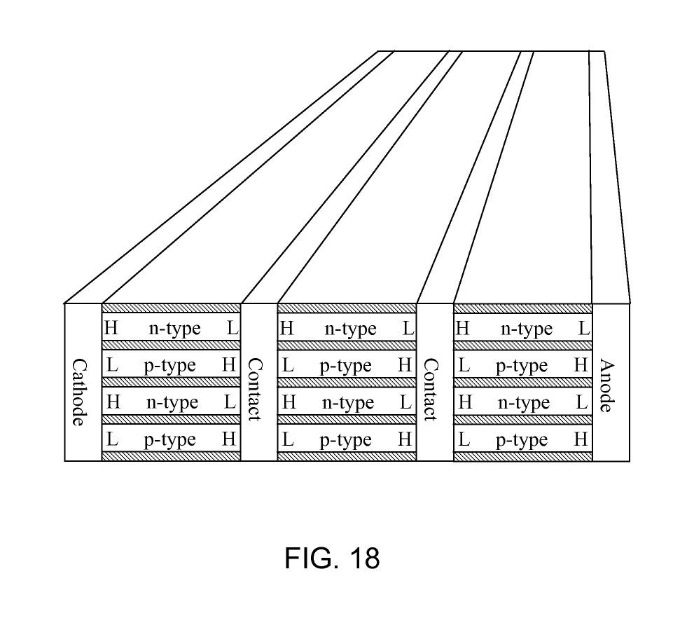

Table 3 presents a few design choices wherein the doping gradient is parallel to the slab layers. The LnH/HpL configuration is shown in FIG. 17. It can easily be assembled in series as illustrated in FIG. 18 to obtain a higher voltage output.

TABLE 3

| | Parallel Gradient | | | |
|---|---|---|---|---|
| | LnH/LnH or | LnH/HpL or | LnH/LpH or | LnH/HnL or |
| | LpH/LpH | LpH/HnL | LpH/LnH | LpH/HpL |
| Large thermal | X | ✓ | X | ✓ |
| contact area | | | | |
| Built-in poten- | ✓ | ✓ | X | X |
| tial across | | | | |
| thermoelectric | | | | |
| material | | | | |
| Current Uni- | ✓ | ✓ | X | X |
| directionality | | | | |

### Example 8

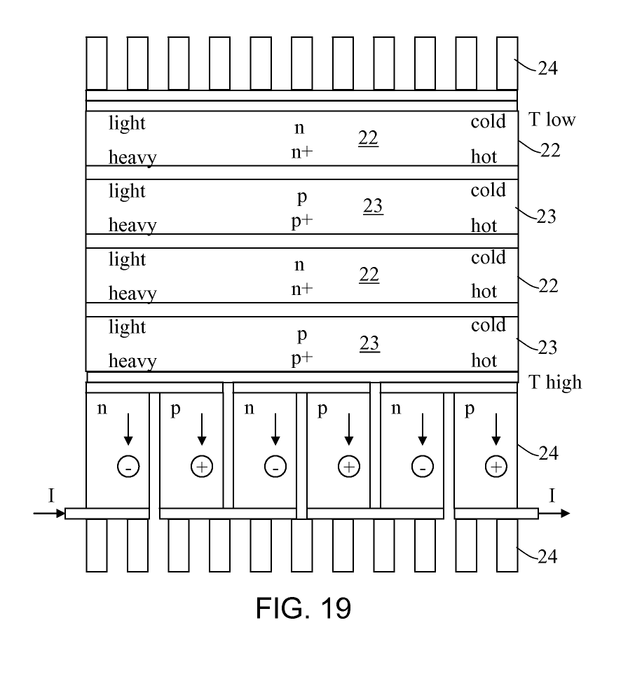

Seebeck junctions are most efficient when they operate between high temperature differences. This can be accomplished by stacking the adiabatic elements so that they generate their temperature differences in series, thereby forming a single adiabatic device. A conventional Seebeck thermoelectric device can then be used to convert this temperature difference into electricity. FIGS. 19 through 23 illustrate a few possible designs that utilize this idea. Those versed in the arts will appreciate that the best performance is achieved when the adiabatic device is thermally matched to the Seebeck device and, depending on their operational characteristics, different geometries and relative dimensions will be required. The match process may also consider economical issues such as the cost of material and fabrication to achieve the best energy production for investment dollar.

FIG. 19 shows an adiabatic device comprising elements 22 and 23 of the type shown in FIG. 5, stacked together and making contact at one end of the stack with a Seebeck device 24. The adiabatic device and the Seebeck device are sandwiched between heat sinks 24. Obviously the elements 22 and 23 can be replaced by electrically controllable elements described in FIGS. 5C, 7, and 8.

### Example 9

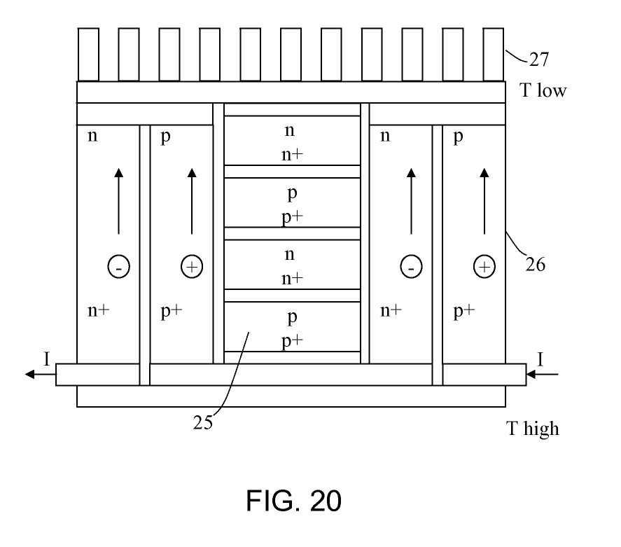

FIG. 20 shows yet another variation wherein the adiabatic device 25 is comprised of several elements described in FIGS. 5-5C arranged in a stack 25. This stack 25 is thermally connected in parallel with a thermoelectric Seebeck generator 26. A cold sink 27 can be mounted on the cold side of the device to extract heat from the environment. This configuration can make use of the well-known thermoelectric checkerboard architecture that includes an array of n and p slabs electrically connected in series and thermally connected in parallel. This architecture can be adapted to produce an electrical generator as follows. For example, a certain percentage of the n and p slabs in the Seebeck generator, say 50%, can be left unaltered and electrically connected in series in the array. The rest of the slabs can be replaced by adiabatic thermal generators thermally connected in series.

### Example 10

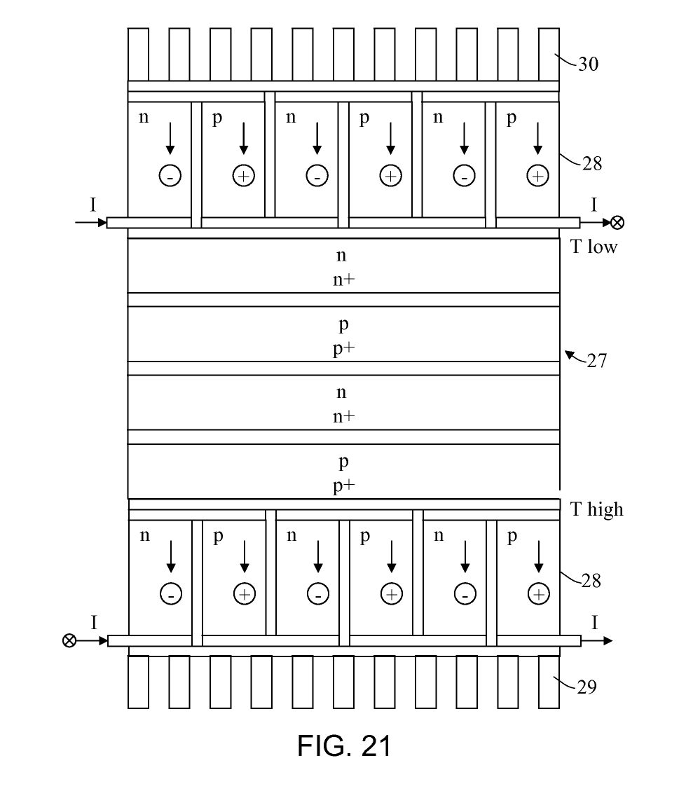

FIG. 21 shows another variation that utilizes one adiabatic thermal generator 27 in a sandwich between two Seebeck generators 28. A heat sink 29 and a cold sink 30 are placed on either side of the device.

### Example 11

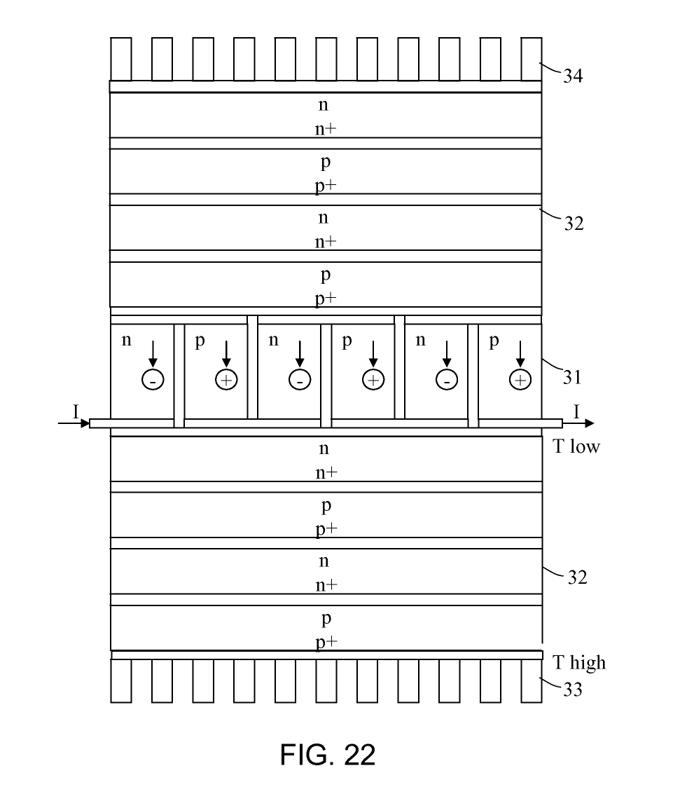

Yet another variation is shown in FIG. 22. A Seebeck thermoelectric generator 31 is placed in a sandwich between two adiabatic thermal generators 32. A heat sink 33 and a cold sink 34 are placed on either side of the device.

### Example 12

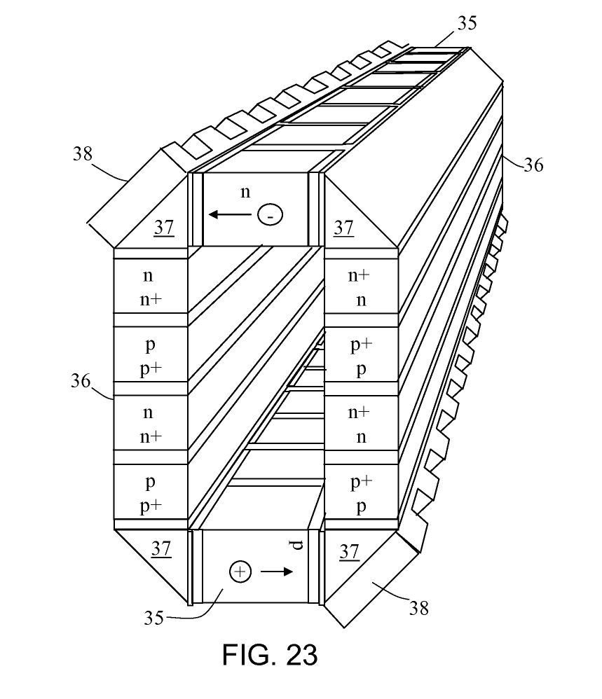

Yet one more variation is shown in FIG. 23. Two Seebeck thermoelectric generators 35 and two thermal generators 36 are placed in a circular configuration such that the thermoelectric generators 35 benefit from the hot and cold output of the adiabatic thermal generators 36. Thermal connections 37 with a triangular cross-section are utilized to allow heat to flow at a 90 degree angle. Cold sinks 38 are placed at the cold locations. The hot locations may be insulated from the environment since the temperature difference across the thermoelectric generators needs to be maximized. It is clear that this variation is not limited to rectangular configuration as shown in FIG. 22 but could include any kind of closed circuit shapes such as hexagons, and more generally polygons.

### Example 13

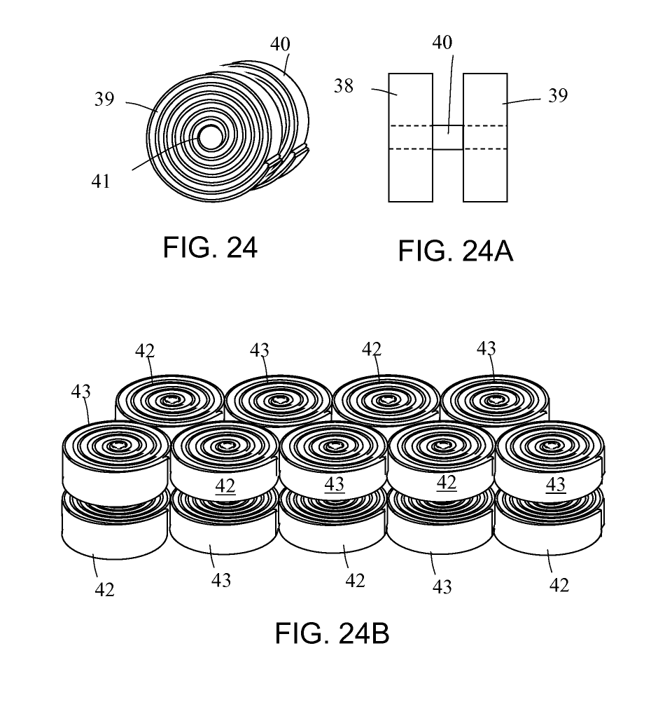

If the semiconductor can be mounted on a flexible substrate layer and rolled as in FIG. 10, it may be possible to construct the device shown in FIGS. 24 and 24A. It comprises two adiabatic devices formed in rolls, the first 38 configured to generate cold at its center, and the second 39 configured to generate heat at its center. The devices are axially and thermally connected by a Seebeck electrical generator 40 thereby generating electricity.

Since heating rolls generate cold as a by-product and cooling rolls generate heat as a by-product, it may be beneficial to alternately assemble heating rolls 42 and cooling rolls 43 as illustrated in FIG. 24B such that they benefit from each other's by-products. Many packing arrangements exist for example, hexagonal as shown in the figure, or square.

In the above discussion it is understood that the adiabatic temperature profile in a semiconductor occurs in the absence of current, and is produced by electrical carriers diffusing up and down the electrical field energy gradient. This energy gradient can be caused by an n+/n or p+/p doping gradient such as, but not limited to, a homo or hetero junction, or a Schottky junction. The energy gradient can also be produced externally by electrodes or even by a magnetic field. Thermoelectric technology, including thermoelectric materials, organic semiconductors, quantum wells, quantum dots, junctions, and thermoelectric architecture, is eminently applicable to this invention. The reader is referred to the vast literature on thermoelectrics.

### Use of Thermoelectric Materials to Generate Photons

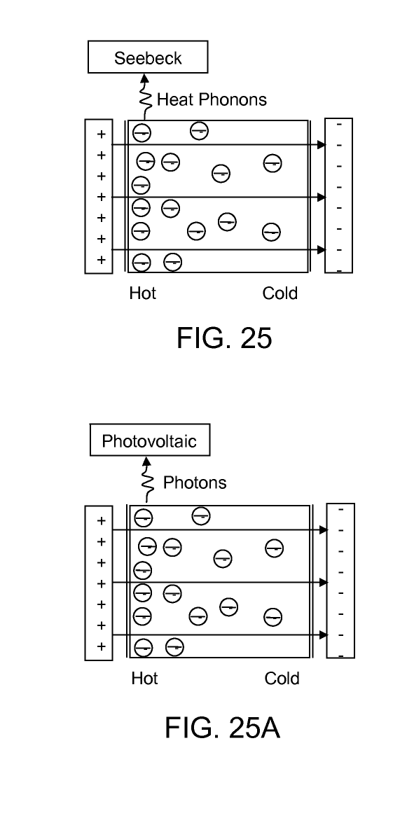

In the above paragraphs we discussed as illustrated in FIG. 25 how an adiabatic rise in temperature in a semiconductor can be used to generate heat phonons which can be either used directly in heating or cooling or inputted into a thermoelectric device to generate electricity. In the paragraphs below we shall see how it is also possible as shown in FIG. 25A for the adiabatic temperature rise to generate photons that can used directly as light or inputted into a photoelectric device to produce electricity. This latter approach has the advantage of not being limited by Carnot efficiency of a heat-to-electricity conversion device such as a thermoelectric generator.

This approach relies on the existence of “hot-electrons” a well known phenomenon in the field of semiconductors. Hot electrons (or hot holes) occur in a semiconductor in which collisions between electrons and lattice atoms is relatively rare, i.e., where the thermal coupling between the electrons and the lattice is weak. When a field is applied to the semiconductor, carriers have more kinetic energy downstream of the field. The low thermal coupling allows carriers to be significantly hotter at the hot end than the lattice.

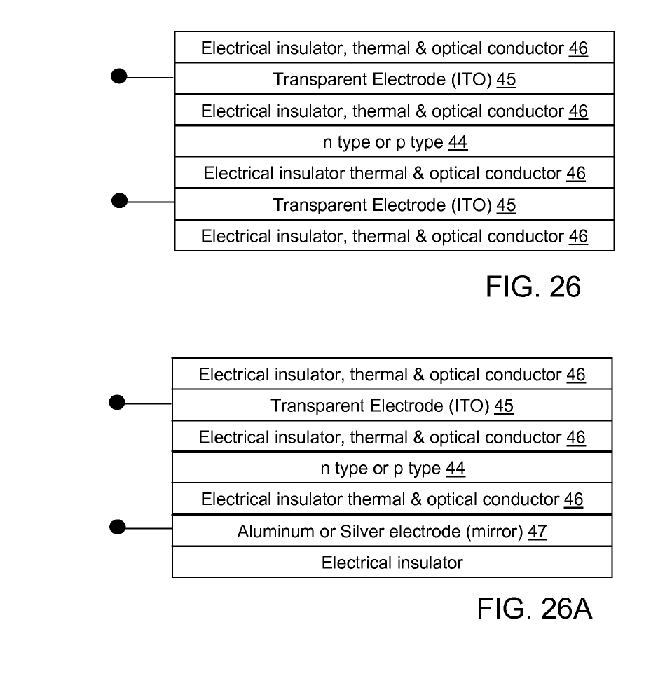

FIG. 26 shows an n-type or a p-type slab 44 of semiconductor material inserted between capacitor plates 45 and insulated by electrically non-conductive layers 46 to prevent current flow. The slab material 44 is selected to have a very low thermal coupling between the carrier and the lattice, except at one of the slab's end where the carriers need to be thermally grounded. For example, if the device requires that hot carriers be produced, then the carriers can be thermally grounded at the cold end which is defined as the end located upstream of the field and vice versa. To minimize the thermal coupling between the carrier and the substrate, the distance between the hot end and the cold end should be kept short, but not too short as to reach or approach breakdown voltage for a given potential difference. Thermal grounding at one end can be achieved by modifying the slab material at that end to have a high thermal coupling for example by disturbing the crystal structure (dislocation zone) or inserting impurities.

The electrodes are made of transparent electrically conductive material 45 such as indium tin oxide or graphene. The insulation 46 is also made of transparent material. FIG. 26 shows a possible implementation wherein both electrodes are transparent, and FIG. 26A shows another implementation where one electrode is transparent and the other 47 is a mirror. A laser could also be created by means of an optical cavity formed by making one electrode a mirror and the other a half silvered mirror.

When a voltage V is applied to the capacitor plates, majority carriers in the semiconductor are adiabatically compressed against one end of the semiconductor slab thereby generating hot carriers with a temperature T=(e/k)V between the two ends of the slab. For V=1 volt, under the ideal situation of zero thermal coupling the temperature of the carrier rises to 11600K. (One needs to emphasize that this is the temperature of the carriers, not of the lattice.) The energy required by an electron to produce green light photons is E=hc/λ or about 2.4 volts 27840K. Applying such a voltage to a slab of semiconductor can only produce green light under ideal conditions, that is, if the thermal coupling between the carriers and the lattice is zero. In practice, the coupling is not zero and the voltage needs to be higher. Of course, if longer wavelength light needs to be generated, then voltages can be lower.

This temperature, together with the applied voltage can be sufficient to generate electron/holes pairs. The majority carriers of such pairs immediately travel toward the hot end and minority carriers, toward the cold end. The newly formed minority carriers recombine with majority carriers thereby generating photons.

The electron-hole generation and subsequent radiative emission disturb the carriers' adiabatic temperature profile, which results in the cooling of carriers at the hot end. This loss of energy diffuses down to the cold end of the slab through the carriers where they are thermally grounded to the lattice. The net result is a lowering of the lattice's temperature and the emission of photons.

A material of particular interest in constructing this device is graphene because of its very low thermal coupling between electrons and lattice.

### Electricity Generation from Adiabatically Generated Photons

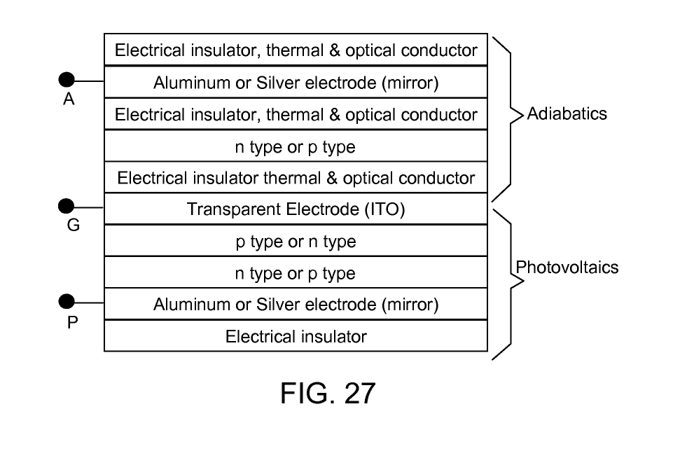

Juxtaposing a photovoltaic device (or a thermophotovoltaic device) with the adiabatic photon generator of FIG. 27 can produce electricity. The photovoltaic device can be tuned to the wavelength generated by the photon generator thereby boosting its efficiency. Three electrodes are required. Electrode G is the ground. Electrode A provides the adiabatic device components with an operating voltage. Since these components are built like a capacitor, no steady state power input into electrode A is required. Electrode P provides the power output from the photovoltaic device.

### Use of Liquid/Vapor Interfaces

The adiabatic effect can also occur at the surface of a liquid in thermodynamic equilibrium with its vapor. The heat of vaporization of the liquid provides the energy gradient. As the most energetic molecules leave the liquid, they convert their kinetic energy into potential energy. Most of these vapor molecules end up colder than the liquid, in other words, with lower kinetic energy than the molecules in the liquid. Conversely, low kinetic energy vapor molecules that fall into, or are captured by the liquid, convert their potential energy into kinetic energy and warm the liquid. Thus when the liquid is in thermodynamic equilibrium with its vapor, the liquid is warmer than the vapor. This phenomenon appears to be paradoxical but is exemplified by superheated water being significantly hotter than its vapor. One must recognized that molecules near a liquid/vapor interface can have at least three potential energy levels, each level accompanied by a corresponding kinetic energy. The first level is in the bulk of the liquid where the potential energy is the lowest and the kinetic energy the highest. The next level is at the surface of the liquid with a higher potential energy and a lower kinetic energy. And the last level is in the vapor phase which has the highest potential energy and the lowest kinetic energy. This energy distribution obeys the equipartition principle.

As already discussed in the context of semiconductor implementation, it is important that the heat be carried only by the adiabatic process which is, in this case, vapor molecules condensating in, and evaporating from, the liquid (i.e., going up and down an energy gradient). Any other heat transfer mechanism would short circuit this process. Therefore, it is desirable to eliminate any thermal short, such as caused by molecules of air or any other gas or vapor not affected by the energy gradient. Therefore, any such molecules must be evacuated from the space holding the vapor. In addition, spacers or any mechanical implements required for separating the surfaces should be as heat insulating and sparse as possible. Furthermore, since a vapor has a low heat conductivity relatively to its liquid or surrounding solids, and since its heat conductivity is a decreasing function of the thickness of the vapor layer (for thicknesses larger than the mean free path), the thickness of the layer must be as thin as mechanically or physically possible (but not necessarily smaller than the mean free path.)

### Use of Hydrophilic and Hydrophobic Surfaces

An interesting implementation involving a liquid/vapor interface makes use of a hydrophilic surface which holds the liquid and is separated by a small gap from a hydrophobic surface. These surfaces present to the liquid and to the vapor different potential energies and therefore acquire different kinetic energies (temperatures). In this situation the hydrophilic surface located at the bottom of the energy gradient is at the higher temperature and the hydrophobic one is at the lower temperature. The technical literature describes in detail hydrophilic, hydrophobic, superhydrophilic and superhydrophobic coatings.

For example, Boreyko et al (Reference 6) describe a heat valve comprising a hydrophilic surface carrying water and is parallel to a hydrophobic surface. Heat transfer in Boreyko's thermal diode is achieved by drop jumping from the hydrophobic surface to the hydrophilic surface. Boreyko does not use the temperature differential generated by the adiabatic evaporation and condensation of vapor molecules.

This invention can use hydrophilic/hydrophobic coats as well as hydrophilic/hydrophobic gels.

To operate with the hydrophilic and hydrophobic surfaces, the working fluid needs to have a greater affinity for the hydrophilic surface than for the hydrophobic surface. For example, it could be polar. Such fluids include water as well as most conventional refrigerant fluids including ammonia. If water/water vapor is selected as a working fluid and is operating near room temperature, the pressure inside the device has to be low since vapor pressure of water is below atmospheric. A fluid with a boiling point near or below room temperature can operate at near or above atmospheric pressure. Non-polar fluids can be used in conjunction with physisorption or chemisorption surfaces assuming the have appropriate affinities with these surfaces. Table 4 lists a few working fluids with their boiling points.

TABLE 4
Boiling Points of Liquids

| | | Boiling Point |
|---|---|---|
| Fluid | | (Degrees Celsius) |
| R-718 | Water | 100 |
| | Diethyl Ether | 34.6 |
| | Ammonia | −33 |
| HCFC-22 | Chlorodifluoromethane | −40.8 |
| HCFC-21 | Dichlorofluoromethane | 8.9 |
| HCFC-124 | 2-Chloro-1,1,1,2- | −12 |
| | tetrafluoroethane | |
| HCFC-141b | 1,1-Dichloro-1-fluoroethane | 32 |
| HCFC-142b | 1-Chloro-1,1-difluoroethane | −10 |
| HC-R601a | Isopentane | 27.7 |
| HC-R601 | Pentane | 36.1 |
| HCC-R30 | Dichloromethane | 39.6 |
| | (Methylene chloride) | |
| HCFC-225ca | | 51 |
| HCFC-225cb | | 56 |

Other design parameters should be considered in the selection of the working fluid. These parameters include the thermal conductivity which affects its heat flow performance. Parameters also include the heat of vaporization which defines the energy gradient. Table 4 is by no means exclusive as there are many other fluids which could be used as working fluids.

There are many ways of constructing an adiabatic thermal generator using a liquid/vapor interface in conjunction with hydrophilic/hydrophobic surfaces. One possible approach is to assemble two heat conductive plates (or foils) in a sandwich. The top plate could be made hydrophobic and the bottom plate hydrophilic. The plates would be separated by spacers and hold between themselves a vapor. The plates would then develop a temperature difference between themselves, which then could be exploited to operate a refrigerator or a heater of to drive a heat engine such as a thermoelectric generator.

Alternatively, if a greater temperature difference is desired (at the expense of a lower thermal conductivity), several such plate or foil sandwiches could be arranged in a stack, with each layer carrying on its top surface a hydrophilic coat and on its bottom surface a hydrophobic coat. The layers are separated from each other by a small gap using thin heat insulating spacers. The hydrophilic surface may carry a thin layer of working fluid in liquid phase and the gap is purged of any gases (to eliminate thermal shorts) except for the vapor of the fluid which is in thermodynamic equilibrium with its liquid phase. In addition the layers should be designed with surfaces having low absorption/radiation characteristics to reduce radiative thermal shorts. A separating gap could also be generated by fabricating spacer from a thin layer, using microlithography or nanolithography.

### Example 14

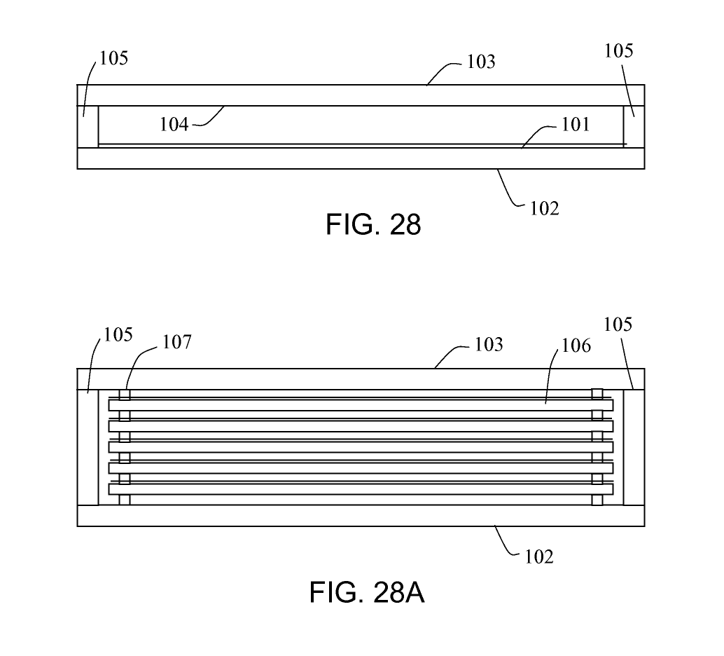

FIG. 28 illustrates one possible implementation for the adiabatic thermal generator using a fluid and hydrophilic/hydrophobic surfaces. It comprises an air-tight box made of two heat conductive plates separated by a heat insulating seal 105 that also acts like a spacer. The bottom plate 101 is coated on its upper surface with a hydrophilic coat 102, and the top plate 103 is coated on its bottom surface 104 with a hydrophobic coat. The box is partially filled with a working fluid to provide enough fluid to cover the hydrophilic surface, but to leave room in the gap between the plates for the vapor phase. The device is warmer on its hydrophilic side (bottom of stack in the figure) than on its hydrophobic side (top of stack). The spacing between the plates can be controlled by means of spacers (for example, the kind used in the Liquid Crystal Devices). For spacings significantly larger than the mean free path of the molecules, the smaller the spacing, the greater the heat conductivity between the plates and therefore the greater the energy throughput of the device.

### Example 15

FIG. 28A illustrates another implementation making use of a stack of heat conductive sheets 106. Each sheet has its top surface carrying a hydrophilic coat and its bottom surface carrying a hydrophobic coat thereby adding in series each of their temperature differences. The sheets are separated by heat insulating spacers 107 and are enclosed in the box of FIG. 28 to seal them from the atmosphere and to conduct heat to and from the outside. Clearly this stacking approach results in an increased temperature differential at the expense of a greater thermal resistivity.

The above discussion regarding the performance of the adiabatic thermal generator device using thermoelectric materials can be adapted to the liquid/vapor interface device. We can define Tₛ as the temperature generated at the liquid/vapor interface. Tₛ is a function of the heat of vaporization H, the heat coefficient of the vapor Cᵥₐₚₒᵣ, and the heat coefficient of the liquid C_{liquid}.

H=Tₛ(Cᵥₐₚₒᵣ+C_{liquid})/2

Let us define coefficient Λ=Kₛ/(Kₛ+Kₚ) where Kₛ is the thermal conductivity to the vapor and Kₚ is the thermal conductivity caused by other components such as the mechanical structure holding the device. As already shown in the section discussing thermoelectric implementation we can show that the power P_{L} at the load is:

$${P}_{L} = \frac{ηΛ {T}_{s}^{2} {K}_{L}}{T} \cdot \frac{{( {K}_{s} + {K}_{p} )}^{2}}{{( {K}_{s} + {K}_{p} + {K}_{L} )}^{2}} .$$

### Where Tₛ=2H/(Cᵥₐₚₒᵣ+C_{liquid})

The maximum power is achieved when the load is matched to the source. K_{L}=Kₛ+Kₚ. With matched load, the maximum power is:

$${P}_{L} = \frac{ηΛ {T}_{s}^{2} {K}_{L}}{4 T}$$

The potential energy gradient in a vapor/liquid interface is due to the heat of vaporization of the liquid. The heat of vaporization is also related in a linear fashion with the surface tension. (Jozsef Garai Physical Model for Vaporization: Journal reference: Fluid Phase Equilibria, 183, 89-92 (2009) Elsevier); Course ChemE 498, Molecular Properties of Gases, Liquids and Solids by Professor Rene M. Overney.—Autumn 2009, Chemical Engineering University of Washington. Gases, Liquids and Solids; and “Other States of Matter” by David Tabor, Cambridge University Press (2003)).

The surface tension manifests itself differently when the liquid comes in contact with hydrophilic and hydrophobic surfaces, indicating the different attractions that these surfaces have for the molecules of the liquid.

The system operates because vapor molecules are more attracted by the hydrophilic surface than by the hydrophobic surface. If water accumulates on the hydrophilic surface, water vapor molecules will simply coalesce with, or separate from, the liquid phase with the accompanying respective production or consumption of vaporization energy. One may conjecture that if droplets of liquid also inappropriately condensate on the hydrophobic surface, the system operation may be reversed because such droplets create an energy well with a gradient in the wrong orientation. However, this problem is self correcting. As long as the temperature difference is not too high, small droplets have a much larger internal pressure than the flat liquid at the hydrophilic surface, and therefore, they have a tendency to evaporate more readily than the flat liquid, thereby transferring their water content from the hydrophobic surface to the hydrophilic surface. (Table 6) The vapor pressure of a curved surface is given by Kelvin equation:

pₛ=p₀exp(2σM/RTρrₖ)

where pₛ=saturation vapor pressure above the flat surface, p₀=saturation vapor pressure above a flat surface, p=density of liquid, M=molar mass, T=temperature, and R=molar gas constant.

TABLE 5
Δp for water drops of different radii
at standard temperature and pressure

| Droplet radius | 1 mm | 0.1 mm | 1 μm | 10 nm |
|---|---|---|---|---|
| Δp (atm) | 0.0014 | 0.0144 | 1.436 | 143.6 |

In conjunction with, or in addition to, the hydrophilic surface and the hydrophilic surface, the liquid can be made to carry a salt such as calcium chloride or sodium chloride in solution. This approach has the advantage of enhancing the transfer of vapor molecules to the liquid by increasing the heat of vaporization of the liquid. In addition, should a drop of pure liquid condensate on the cold wall, this drop will have the tendency to evaporate and the vapor to return to the salt-spiked liquid.

The liquid can be held in place by a gel to prevent it from sloshing around and make contact with the hydrophobic surface. Alternatively, the liquid can be held in place by roughening the surface of the hydrophilic layer or configuring it as a sponge.

### Example 16

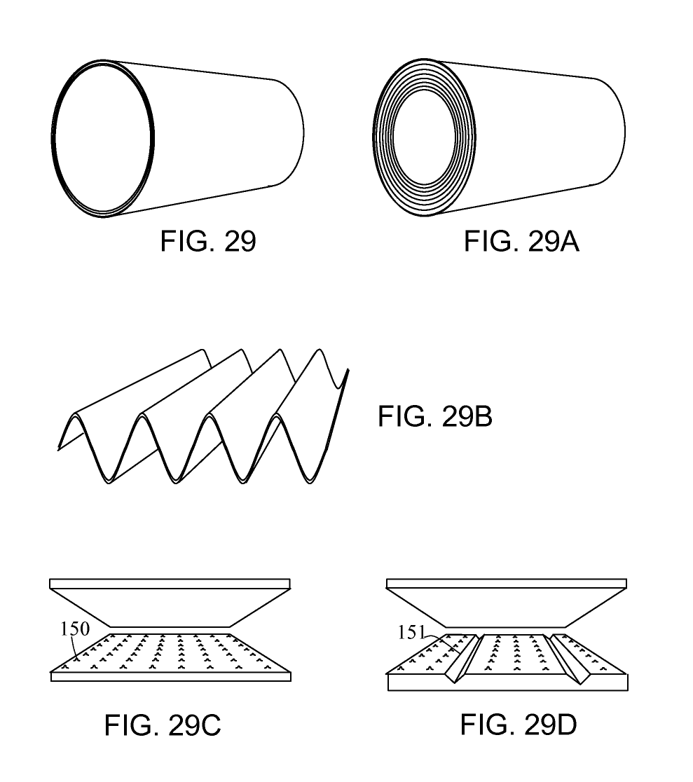

The stack of FIG. 28 can be configured as a series of concentric cylinders as shown in FIG. 29. The multilayer stack of FIG. 28A can be configured as a series of concentric cylinders as shown in FIG. 29A or a series of rectangular or square boxes as shown in FIG. 9. Clearly many shape variations are possible. The cylinders are separated from each other and held in place by heat insulating spacers. Obviously the ends of the cylinder or box have to be sealed to prevent the working fluid from escaping. These pipes can be configured as heating or cooling devices depending on whether the hot side is inside or outside the pipe.

FIG. 29B illustrates how a hydrophobic surface and a hydrophilic surface can be brought together in the form of heat fins. This configuration aims at maximizing the surface area in contact with either sides of the device.

### Example 17

A single sheet, for example of metal foil carrying on one side a hydrophilic coat and on the other, a hydrophobic coat, could also be wrapped into a cylindrical roll, or a rectangular or square box. Heat insulating spacers can also be used to separate the successive turns of the roll. Alternatively to the spacers, a very light gauze or mesh material could be wound with the sheet as a means for separating the turns. The ends of the roll have to be sealed to prevent the working fluid from escaping. One must reiterate the goal of minimizing heat flow through the gauze of mesh and through any gas not susceptible to the forces at the hydrophilic and hydrophobic surfaces.

Multilayer hydrophobic/hydrophilic devices can also employ different vapors between successive layers, each vapor being selected to operate optimally in the temperature range of the layer. For example if a freezer needs to operate between 20C (environment temperature) and −20C (freezer temperature) a two-gap, three layer device could be used. The external gap (warm side) would then be filled with water vapor and the inside gap (cold side) would be filled with ammonia vapor. The coating of each layer would be selected to operate with the corresponding vapor. A similar approach could be taken in the design of gas with adsorbing/non-adsorbing coating, to be discussed below.

The above discussion describes adiabatic thermal generators using liquid/vapor interfaces and hydrophilic and hydrophobic surfaces. To construct electrical generators the same configurations as those already described in the context of thermoelectric materials can also be used, in particular those shown in FIGS. 19 thru 24.

Table 6 shows some physical parameters of interest for some liquids.

TABLE 6
Physical Properties of some liquids

| | | | | | | Surface |
|---|---|---|---|---|---|---|
| | | Boiling | Heat of | | | tension |
| | | Point | Evaporation | Density | Dipole | at 20 C. |
| Liquid | Formula | (° C.) | (J/kg) | (gm/ml) | Moment | dyn/cm |
| Dichloromethane | CH₂Cl₂ | 40 | 170 | 1.3266 | 1.60 D | 27.36 |
| (DCM) | | | | g/ml | | |
| Tetrahydrofuran | /—CH₂—CH₂—O— | 66 | 444 | 0.886 | 1.75 D | 28 |
| (THF) | CH₂—CH₂—\ | | | g/ml | | |
| Ethyl acetate | CH₃—C(=O)—O— | 77 | 404 | 0.894 | 1.78 D | 23.6 |
| | CH₂—CH₃ | | | g/ml | | |
| Acetone | CH₃—C(=O)—CH₃ | 56 | 518 | 0.786 | 2.88 D | 23.7 |
| | | | | g/ml | | |
| Ammonia | N—H₃ | −33 | 1369 | | 1.42 D | 23.4 |
| Ethanol | CH₃—CH₂—OH | 79 | 846 | 0.789 | 1.69 D | 22.27 |
| | | | | g/ml | | |
| Methanol | CH₃—OH | 65 | 1100 | 0.791 | 1.70 D | 22.6 |
| | | | | g/ml | | |
| Water | H—O—H | 100 | 2257 | 1.000 | 1.85 D | 71.97 |
| | | | | g/ml | | |

### Use of Adsorption of Gases on Surfaces

The adiabatic process can also occur when a gas is subjected to van der Waals force on an adsorbing surface. The adsorption can be either physisorption or chemisorption. Clearly, the vapor implementation discussed above becomes the gas implementation when the gap between the plates contains vapor without any liquid.

As discussed above, the performance of the device depends on the temperature difference achieved between the two plates. This difference is a function of the thermal conductivity of the gas adiabatically interacting with the van der Waals force. Since hydrogen has a relatively high conductivity in comparison to other gases, it is a good choice as a working fluid. Other good working fluids include low atomic weight gases and vapors such as methane, ammonia and water vapor.

If the temperature of the device gets too low, its performance decreases since the thermal conductivity of the gas is proportional to the square root of the temperature. It is therefore important to raise the operation temperature of the device by means of a cold sink that increases the heat exchange between the cold side of the device and the environment.

Other conductivities not associated with such adiabatic interaction result in thermal shorts and should be minimized. These conductivities are due to the spacers and the supporting structure separating the walls. These conductivities are also caused by “non-adiabatic” interaction of the hydrogen molecules with the walls of the container, that is, interactions wherein hydrogen molecules do not experience any adsorbing force. Such interactions may occur, for example, if the walls become saturated with adsorbed molecules. The walls then cease to operate as adsorbers and become thermal shorts. This situation can be avoided by keeping the pressure low enough that a large fraction, for example 25%, or possibly only 5%, of the adsorption sites are used.

To maximize the thermal conductivity of the gas in the device, the spacing between the floor and the ceiling of the device should be as small as possible subject to manufacturing and operational constraints. The spacing could range from 0.1 micron to 1 millimeter, preferably from 1 micron to 100 microns.

FIG. 29C illustrate how spacers 151 can be molded directly on one of the surfaces. One of the surfaces can be embossed with small protuberances 150 that act as spacers. This approach minimizes the heat conductivity between the surfaces by reducing their contact areas.

In addition, if a vacuum or partial vacuum is to be produced in the gap between the surfaces it may be advantageous to speed up fluid flow by slotting one of the surfaces with grooves 151 as shown in FIG. 29D. The grooves would then converge to an input/output port leading to a vacuum pump that would be used to evacuate the air. Furthermore, the grooves could also be used to fill the gap with the working gas or vapor. Obviously, the plate sandwich would have to be sealed around its perimeter. The protuberances and grooves can be produced by any number of metal forming processes including rolling, casting and pressing.

Performance can also be maximized by selecting adsorbers with relatively strong adsorbing energy, with the constraint that 1) a large proportion of the adsorption sites remain unoccupied, which implies low pressure, and 2) enough pressure be left within the gas to sustain good heat conductivity. Since heat conductivity is mostly independent of pressure, and drops only at very low pressure, one can conclude that low pressure operation is desirable, ranging from 0.000001 atmosphere to 1 atmosphere, more preferably from 0.001 atmosphere to 0.1 atmosphere.

The literature abounds with hydrogen adsorbers which have been developed for hydrogen storage including boron oxide, nickel, platinum, palladium, activated carbon, alumina, etc.

### Example 18

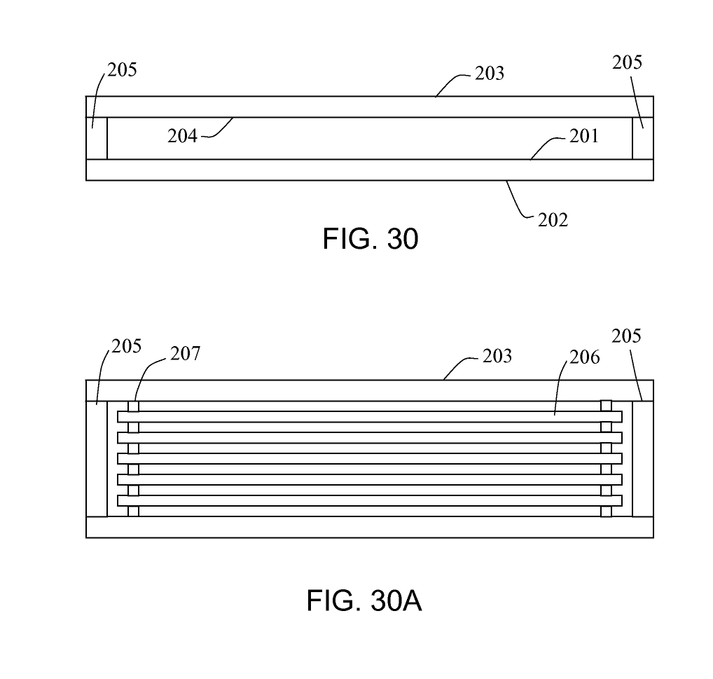

This embodiment utilizes a reaction chamber as in FIG. 30 wherein the top surface 201 of the bottom plate 202 carries a high adsorbency coat (such as alumina), and the bottom surface 204 of the top plate 203 carries a low adsorbency coat. The plates are heat conductive and separated by heat insulating spacers. The gas (for example hydrogen) between the plates is selected for its high thermal conductivity and its adsorption characteristics. If the plates 203 and 202 are made of aluminum, the top surface 201 of the bottom plate could be oxidized to a layer of alumina. The bottom surface 204 of the top plate 202 could be passivated with a coat or doping of MnCl₂.

### Example 19

FIG. 30A illustrates another implementation making use of a stack of heat conductive sheets 206. Each sheet has its top surface carrying an adsorbent coat and its bottom surface, a non-adsorbent coat thereby adding in series each of their temperature differences. The sheets 206 are separated by heat insulating spacers 207 and are enclosed in the box of FIG. 30 to seal them from the atmosphere and to conduct heat to and from the outside. Heat sinks and cold sinks can be mounted on the plates 202, and 203 to improve their heat conduction capabilities. The surface of the sheets would be treated as described in the example above.

### Example 20

The stack of FIG. 30A can be configured as a series of concentric cylinders as shown in FIG. 29, or a series of rectangular or square boxes as shown in FIG. 9. The cylinders are separated from each other and held in place by heat insulating spacers. The thermal conductivity of the spacers needs to be kept as low as possible to maximize the performance of the device. Obviously the ends of the cylinder or box have to be sealed to prevent the working fluid from escaping.

### Example 21

A single sheet, for example of metal foil carrying on one side an adsorbent coat could also be wrapped into a cylindrical roll, or a rectangular or square box. Heat insulating spacers can also be used to separate the successive turns of the roll. Alternatively to the spacers, a light gauze or mesh material could be wound with the sheet as a means for separating the turns. The ends of the roll have to be sealed to prevent the working fluid from escaping.

Clearly other gases beside hydrogen and other adsorbents beside alumina are possible. Different gas/adsorbent combinations may be more desirable than others depending on the environmental temperature and operating conditions.

As already shown in the context of thermoelectric implementations, Seebeck junctions can be used to generate electricity from adiabatic thermal generators.

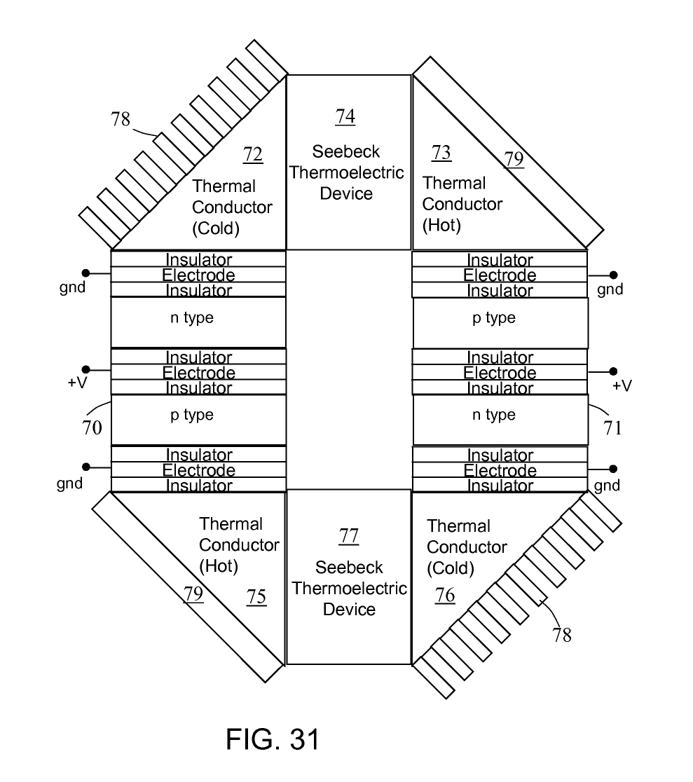

FIGS. 31 through 34 show different possible architectures. In FIG. 31 two stacks 70 and 71 of n and p type semiconductors are positioned side by side and antiparallel configuration. The voltage +V is applied such as to attract carriers in the n type material and repel carriers in the p type material thereby generating hot regions in the upper left and lower right, and cold regions in the upper right and lower left. The hot region and cold region at the top are joined together by means of triangular conductive prisms 72, 73 through a Seebeck device 74 thereby generating electricity. The hot region and cold region at the bottom are similarly joined by triangular prisms 75 and 76 and by a Seebeck device 77 to generate electricity. The prisms connected to the cold regions are equipped with cold sinks 78 to replenish the heat used up in the generation of electricity. Insulating layers 79 cover the hot surfaces and preserve the heat of the device.

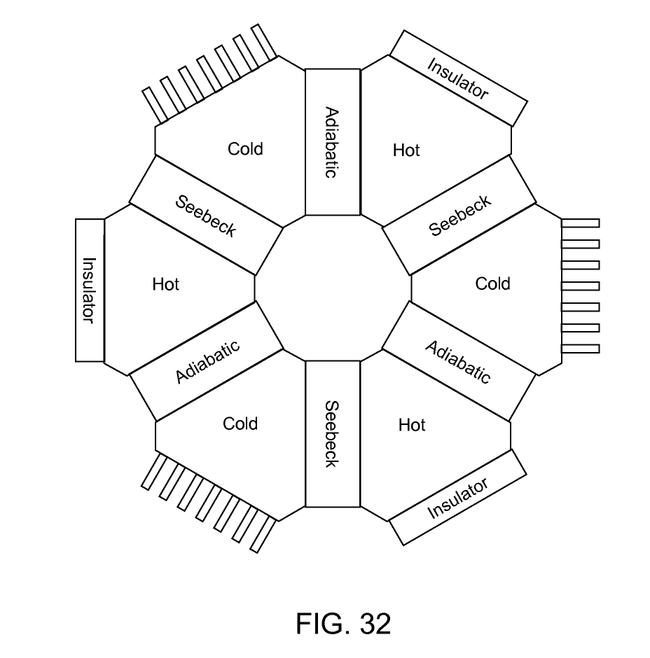

The device shown in FIG. 32 is identical to the one in FIG. 31 except that it has a hexagonal configuration instead of a rectangular one.

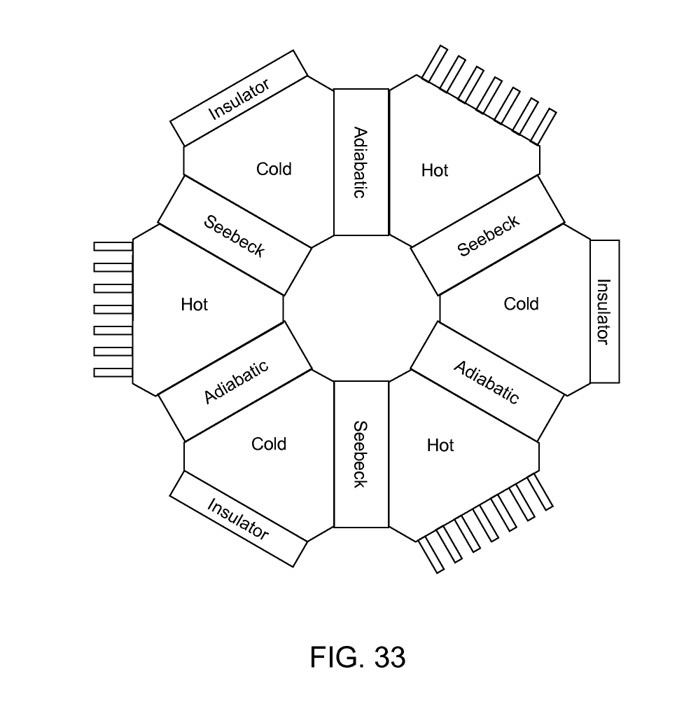

In FIG. 33 the position of the heat sinks and insulator layers are reversed thereby forcing the device to operate at low temperature. This configuration may be advantageous if the performance characteristic of the adiabatic device and Seebeck junction improves with a lowering of the temperature, possibly if the thermoelectric device needs to be operating in a superconducting mode.

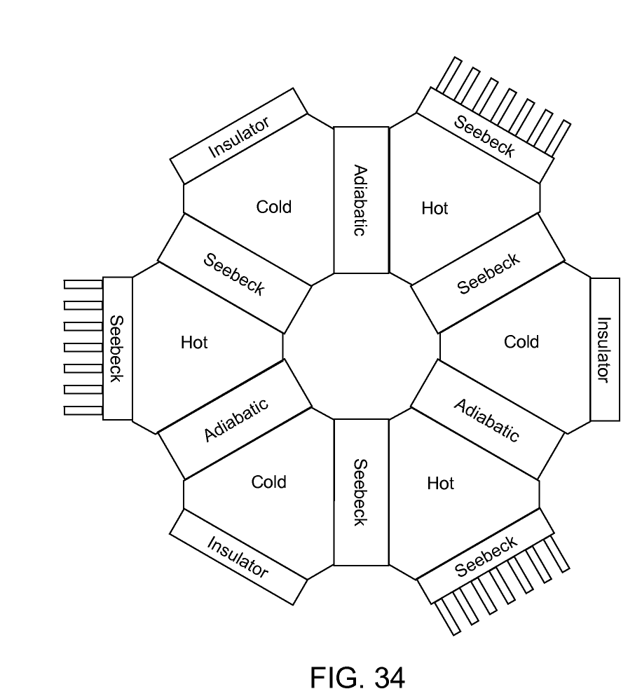

In FIG. 34 the heat sinks are serially connected to the device by means of Seebeck devices 80. As the temperature of the assembly goes down, these serially connected Seebeck devices 80 also generate electricity.

The gap between a hydrophobic surface and the hydrophilic surface needs to contain water vapor (or any other working vapor) and to be evacuated of parasitic thermal shorting gases such as air. Since the gap could range from 100 nanometers to 100 microns, the air flow could be very slow and the evacuation process could take a long time. To speed up this process during manufacturing, the surfaces could be configured with grooves, typically covering less than 10% of the surface, to channel the gas outside. The same argument is applicable to the adsorption version. The grooves could be formed by press rolling or any conventional and suitable material forming process. Alternatively, the hydrophobic/hydrophilic sandwich could be assembled in an atmosphere comprised of the desired vapor or gas, and devoid of any other parasitic species.

FIG. 29B illustrates how an adsorbing surface and a non-adsorbing surface can be brought together in the form of heat fins. This configuration aims at maximizing the surface area in contact with either side of the device.

### Use of Polar Molecules

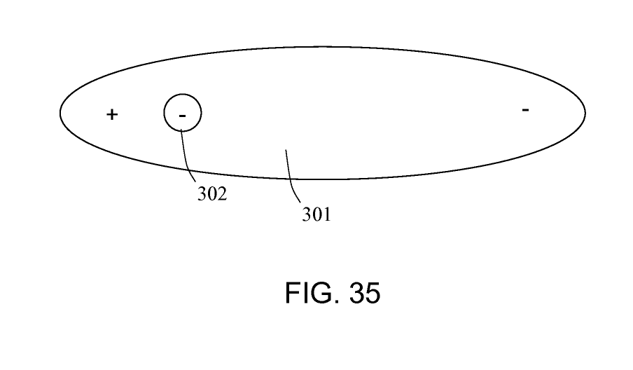

Yet another application shown in FIG. 35 utilizes the adiabatic temperature distribution of at least one electron 302 (or hole) in a polar molecule 301. The electron 302 (or hole) is in the conduction band of, but confined to, the polar molecule 301. The potential energy gradient is caused by the electric field generated by the polar molecule 301. The gas phase's thermal conductivity corresponds to the thermal conductivity of the electron 302 (or hole). The supporting structure is the polar molecule (301) itself. The thermal conductivity of the supporting structure is the thermal conductivity between the two polar ends, not caused by the electron 302 (or hole). This conductivity may be caused by phonons traveling between the two ends of the molecule or by agents outside the molecules (e.g., other molecules). The cold region is that polar end away from which the electron or hole is repelled by the electric field, and the hot region is the polar end toward which the electron or hole is attracted by the electric field.

### Applications

This invention relies on the adiabatic effect to produce a temperature difference. This adiabatic effect is a thermo-motive force that operates naturally and that requires heat to flow from a cold region to a hot region under the influence of a force field, without the need for an external power source. This thermo-motive force is the result of the generalized Clausius' formulation of the Second Law discussed above, that requires heat to flow down a relative temperature gradient, where the gradient is relative to the adiabatic temperature distribution produced by the force field.

The adiabatic effect allows many kinds of applications including heat transport applications and electricity generation applications.

Heat transport applications simply create a temperature difference without requiring any power input by moving heat from a cold location to a hot location. Applications include but are not limited to refrigerators, heaters, air conditioners and heat pumps.

Applications also include controllable and reversible heaters and coolers. A voltage applied between two capacitively coupled plates can be used to control the electrical field going through a thermoelectric material placed between (but insulated from) the plates. Since the electrical field is required for the adiabatic effect in the thermoelectric material, the voltage can be used to control the magnitude and the direction of the thermo-motive force. Thus a heater could become a refrigerator and vice versa.

Applications of this technology include refrigerators and heaters that can operate without requiring an electrical power input. When this technology is associated with thermal to electrical generators (such as thermoelectric devices) it can be used to generate electric power. Electrical generators using this technology draw power directly from their environments leaving cold as a by-product.

Yet other applications include power supplies for semiconductor chips and semiconductor modules. These power supplies can be fabricated as integral subcomponents of these chips or modules. Since the by-product of these power supplies is cold, these power supplies can also serve as coolers for the chips or modules. In essence the heat energy generated by semiconductor chips can be captured and reused by the chips.

Applications include heat pumps for example:

Refrigerators that do not require input power. The by-product is heat.

Heaters that do not need fuel or electricity. The by-product is cold

Switchable heat pumps (Heating [symbol] Refrigeration)

Indoor climate control

Other applications include electricity generation, for example:
Forever Batteries—Output is electrical power, by-product is cold
Wireless Forever Lights—With embedded LED, by-product is cold
Self-powered Semiconductor chips—Recycle their own energy
Self powered electrical cars with infinite range, no exhaust, no recharge
Self-powered houses independent of the electrical grid.
Less need or no need for power transmission lines.

Food Packaging, Storage and Preparation are also possible applications of this technology. Applications include:
Food containers with a switchable heat pump to keep the food frozen during transportation and storage. Before consumption, the heat pump is switched to a heater mode.
Refrigerators can operate without power input—by-product is heat.

While the above description contains many specificities, the reader should not construe these as limitations on the scope of the invention, but merely as exemplifications of preferred embodiments thereof. Those skilled in the art will envision many other possible variations within its scope. Accordingly, the reader is requested to determine the scope of the invention by the appended claims and their legal equivalents, and not by the examples which have been given.

I claim:

1. An energy generator capable of transferring heat across a volume from a cold region to a hot region and comprising:
a. particles in a gas phase;
b. a supporting structure restraining said particles to said volume;
c. a force field producing a gradient in potential energy in said volume, said particles being subjected to said force field and, consequently, developing a non-uniform distribution in temperature resulting in a temperature difference between said cold region and said hot region;
d. said gas phase having a gas phase's thermal conductivity;
e. said supporting structure having a supporting structure's thermal conductivity; and
f. ratio of said gas phase's thermal conductivity to said supporting structure's thermal conductivity being selected to be sufficiently high to produce said temperature difference.

2. The energy generator of claim 1 comprising:
a. a first heat transfer occurring by diffusion through said gas phase from said cold region to said hot region, in accordance with said thermal conductivity of said gas phase, said first heat transfer being a result of an effect dubbed thermo-motive force caused by said force field and said first heat transfer contributing to increasing said temperature difference between said cold region and said hot region;
b. a second heat transfer also called thermal short circuit, occurring from said hot region to said cold region, said second heat transfer being a function of said supporting structure's thermal conductivity, said second heat transfer contributing to reducing said temperature difference between said cold region and said hot region; and
c. combination of said first heat transfer and said second heat transfer resulting in said temperature difference between said cold region and said hot region.

3. The energy generator of claim 1 wherein said force field is an electrical field, said particles are electrons or holes behaving as a gas in a semiconductor slab, said gas phase's thermal conductivity is the thermal conductivity of said electrons or holes, said supporting structure is said slab of semiconductor material and said supporting structure's thermal conductivity is mediated by phonons or photons in said slab.

4. The energy generator of claim 3 wherein said electrical field is produced by a doping gradient or junction in said slab.

5. The energy generator of claim 3 wherein said doping gradient or junction comprises a material of the n+/n type or of the p+/p type.

6. The energy generator of claim 3 wherein said electrical field is produced by electrodes external to said slab, said electrons or holes being constrained by electrical insulation not to flow as a direct current through said slab.

7. The energy generator of claim 3 wherein said slab comprises a quantum well material.

8. The energy generator of claim 3 wherein said temperature difference generates hot carriers in said slab, said hot carriers generating photons.

9. The energy generator of claim 3 also comprising a photovoltaic device, wherein said temperature difference generates hot carriers in said slab, said hot carriers generating photons, said photons being captured by said photovoltaic device thereby generating electricity.

10. The energy generator of claim 1 wherein
a. said particles are molecules of a vapor above the surface of a liquid corresponding to said vapor;
b. said potential energy gradient is caused by the heat of vaporization of said liquid;
c. said gas phase's thermal conductivity is the thermal conductivity of said vapor;
d. said supporting structure includes a container made of a solid material, holding said vapor and said liquid;
e. said supporting structure's thermal conductivity is mediated by at least one element selected from the group consisting of phonons travelling in said solid material of said container, photons being exchanged between said walls, and other molecules different from and mixed with said vapor molecules, and unaffected by said heat of vaporization; and
f. said cold region is a first set of walls of said container in contact with said vapor and said hot region is a second set of walls of said container in contact with said liquid.

11. The energy generator of claim 10 wherein said first set of walls has a hydrophilic surface in contact with said liquid and said second set of walls has a hydrophobic surface in contact with said vapor, said liquid selected to be affected by said hydrophilic surface and said hydrophobic surface.

12. The energy generator of claim 10 wherein said liquid carries a salt as a solute.

13. The energy generator of claim 1 wherein:
a. said particles are molecules of an adsorbate gas above an adsorbing surface;
b. said potential energy gradient is caused by van der Waals force at said adsorbing surface acting on said adsorbate gas;
c. said gas phase's thermal conductivity is the thermal conductivity of said adsorbate gas;
d. said supporting structure includes a container made of a solid material, holding said adsorbate gas, a first set of said walls of said container configured as adsorber walls for said adsorbate gas and a second set of walls configured as non-adsorber walls for said adsorbate gas;
e. said supporting structure's thermal conductivity being mediated by at least one element selected from the group consisting of phonons travelling in said solid material of said container, photons being exchanged between said walls of said container, and non-adsorbate gas molecules mixed with said adsorbate gas molecules but not affected or affected to a lesser extent than said vapor molecules by said van der Waals force; and
f. said cold region is said non-adsorber walls and hot region is said adsorber walls.

14. The energy generator of claim 13 wherein:
a. said adsorbate gas is hydrogen;
b. said adsorbing surface having adsorbing sites, said adsorbing sites not more than 25% bound to atoms of said hydrogen;
c. said adsorber walls being separated from non-adsorber walls by no more than 1 millimeter.

15. The energy generator of claim 13 wherein said adsorber walls are separated from non-adsorber walls by no more than 1 micron.

16. The energy generator of claim 1 wherein
a. said particles are at least one electron or hole and confined to a polar molecule, said particle in a conduction band of said polar molecule, said polar molecule having two polar ends;
b. said potential energy gradient is caused by an electric field generated by said polar molecule;
c. said gas phase's thermal conductivity is the thermal conductivity of said at least one electron or hole;
d. said supporting structure includes said polar molecule;
e. said supporting structure's thermal conductivity is a thermal conductivity between said polar ends, not caused by said at least one electron; and
f. said cold region is one of said polar ends and repels said electron or hole, and said hot region is one of said polar ends and attracts said electron or hole.

17. The energy generator of claim 1 wherein said ratio is greater than 5.

18. The energy generator of claim 1 configured to produce said temperature difference with said cold region located inside of a refrigerator and said hot region located outside of said refrigerator.

19. The energy generator of claim 1 configured to produce said temperature difference with said hot region located inside of a heater and said cold region located outside of said heater.

20. The energy generator of claim 1 configured to produce said temperature difference across a thermoelectric device thereby converting heat to electricity.
